(19) United States
(12) Patent Application Publication
(10) Pub. No.: US 2026/0324036 A1
(43) Pub. Date: Oct. 15, 2026

(54) Blocking Structures for Conductive Layers in Semiconductor Devices and Methods of Manufacturing the Same

(71) Applicant: Texas Instruments Incorporated, Dallas, TX (US)

(72) Inventors: Wolfgang Weiss, Landshut (DE); Jeffrey A. Babcock, Sunnyvale, CA (US); Malik Ahmad Faraz, Freising (DE); Antonio Gallerano, Sachse, TX (US)

(21) Appl. No.: 19/176,391

(22) Filed: Apr. 11, 2025

(51) Int. Cl. H10D 64/00; H10D 30/01; H10D 62/10; H10D 62/13; H10D 62/17

(52) U.S. Cl. CPC H10D 64/118; H10D 30/027; H10D 62/115; H10D 62/151; H10D 62/235

(57) ABSTRACT

A semiconductor device and methods of manufacturing the same are disclosed herein. The device includes a first semiconductor region disposed over a substrate and the first semiconductor region has a first conductivity type. The device further includes a second semiconductor region disposed over the substrate and having a second conductivity type opposite the first conductivity type. The device further includes an isolation structure disposed over the substrate that abuts the second semiconductor region. The device further includes a blocking structure straddling over a first portion of the second semiconductor region and a portion of the isolation structure. The device further includes a conductive layer disposed over a second portion of the second semiconductor region and abuts the blocking structure.

### FIELD

The present disclosure generally relates to semiconductor devices, and more particularly, to blocking structures for conductive layers in semiconductor devices including silicide blocking structures that block the formation of silicide.

### BACKGROUND

Integrated circuits may involve the formation of silicide on various components during semiconductor manufacturing processes. In some examples, silicide may be used to improve electrical conductivity between different layers of a semiconductor device. In other examples, silicide may be used to reduce interface resistance between an overlying conductive feature (e.g., metal layer) and an underlying semiconductor layer. Still further, in other examples, silicide may be used as a diffusion barrier to prevent diffusion of atoms (e.g., metal atoms) from an overlying layer (e.g., metal layer) into an underlying semiconductor layer. Thus, the formation of silicide in semiconductor manufacturing processes may play an important role in a device’s overall performance and reliability.

### SUMMARY

Disclosed herein is a device including a first semiconductor region disposed over a substrate. The first semiconductor region having a first conductivity type. The device further including a second semiconductor region disposed over the first semiconductor region. The second semiconductor region having a second conductivity type opposite the first conductivity type. The device further including an isolation structure disposed over the substrate. The isolation structure abutting the second semiconductor region. The device further including a blocking structure straddling over a first portion of the second semiconductor region and a portion of the isolation structure. The device further including a conductive layer disposed over a second portion of the second semiconductor region. The conductive layer abutting the blocking structure.

Also disclosed herein is a device including a first semiconductor region and a second semiconductor region disposed over a substrate. The first semiconductor region having a first conductivity type and the second semiconductor region having a second conductivity type that is opposite the first conductivity type. The device further including an isolation region disposed adjacent to and laterally surrounding the first and second semiconductor regions. The device further including a blocking structure straddling over a first portion of the second semiconductor region and a portion of the isolation region. The device further including a conductive layer disposed over a second portion of the second semiconductor region.

Also disclosed herein is a method including forming a dielectric isolation structure in a semiconductor layer. The method further including forming a blocking layer over a first portion of the semiconductor layer and over a portion of the dielectric isolation structure. The method further including forming a conductive layer over a second portion of the semiconductor layer.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a flowchart for a method of forming a semiconductor device, in accordance with various examples.

FIGS. 2A, 2B, 2C, 2D, 2E, 2F, 2G, 2H, 2I, 2J, 2K, 2L, 2M, 2N, and 2O illustrate cross-section views of various semiconductor devices, in accordance with the process of FIG. 1 and the various examples associated therewith.

FIGS. 3A, 3B, 3C, 3D, 3E, and 3F illustrate top-down, plan views of various semiconductor devices, in accordance with the process of FIG. 1 and the various examples associated therewith.

FIGS. 4A and 4B illustrates a cross-section view of various semiconductor devices, in accordance with the process of FIG. 1 and the various examples associated therewith.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended for simplicity and clarity of description and is not intended to form or dictate a relationship between different examples described herein. The examples and descriptions provided herein are intended to be illustrative and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two. For example, “on” may be used to indicate direct contact between the two and “over” may be used to indicate one or more intervening layers between the two.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

The present disclosure relates generally, but not exclusively, to semiconductor manufacturing processes for forming blocking structures that prevent (or block) the formation of conductive layers in semiconductor devices. In some examples, a blocking structure is formed that prevents (or blocks) the formation of silicide (e.g., conductive layer) along portions (e.g., edges) of semiconductor regions (e.g., doped semiconductor regions, source/drain regions, active regions, or the like) that may help reduce leakage current in a semiconductor device as described in further detail below.

In that regard, silicide (e.g., conductive layer, silicide layer, metal silicide layer, or silicide feature) may be composed of silicon and a metal such as titanium (Ti), nickel (Ni), cobalt (Co), tungsten (W), molybdenum (Mo), platinum (Pt), chromium (Cr), or the like. For example, the formation of silicide may include a metal layer being formed over a semiconductor region (e.g., doped semiconductor region, source/drain region, active region, etc.) that includes silicon and then subjected to an annealing process causing the metal layer to react with (or diffuse into) the semiconductor region. That is, the metal atoms from the metal layer react with silicon from the semiconductor region to form silicide over the semiconductor region of the semiconductor device. In various examples, the semiconductor device may be or include a diode, a bipolar junction transistor (BJT), a field effect transistor (FET), the like, or a combination thereof. Several such examples will be described in more detail below.

In some examples, the semiconductor region (e.g., doped semiconductor region, source/drain region, active region, etc.) may be isolated by an isolation structure (e.g., shallow trench isolation structure, deep trench isolation structure, local oxidation of silicon structure, or the like) that is disposed adjacent the semiconductor region. Because of the various processing steps that may be used to form the semiconductor region and/or the isolation structure, in various examples, the respective top surfaces of the semiconductor region and the isolation structure may or may not be substantially planar with respect to each other. For example, etching and/or planarization processes (e.g., chemical mechanical polishing (CMP), etc.) may result in the top surface of the isolation structure being (i) substantially planar to the top surface of semiconductor region, (ii) recessed (e.g., lower) relative to the top surface of semiconductor region, and/or (iii) elevated (e.g., higher) relative to the top surface of semiconductor region.

In such examples where the top surface of the isolation structure is recessed relative to the top surface of semiconductor region, sidewall surfaces (e.g., side edges) of the semiconductor region may be unintentional exposed. As such, the silicide may form along the exposed sidewall surfaces in addition to the top surface of the semiconductor region. Moreover, regardless of the relative orientation of the top surfaces of the isolation structure and the semiconductor region, certain undesirable characteristics associated with having different materials adjoined (e.g., the stress caused by the interface between the different materials forming the isolation structure and the semiconductor region) may allow for the formation of silicide along sidewall surfaces (or edges) of the semiconductor region. The formation of silicide along the sidewall surfaces of the semiconductor region may lead to leakage current issues that are detrimental to the performance and reliability of the semiconductor device.

To address these issues, a patterned silicide blocking layer (e.g., blocking structure) may be formed over the interface between the semiconductor region and the isolation structure before forming the silicide. In other words, a patterned silicide blocking layer may straddle (or overlap) portions of the semiconductor region and the isolation structure such that the interface between the semiconductor region and the isolation structure is covered by the patterned silicide blocking layer. Such positioning (or orientation) of the patterned silicide blocking layer, in various examples, prevents the formation of silicide on portions of the semiconductor region at and/or around the interface between the semiconductor region and the isolation structure which may decrease leakage current in the semiconductor device.

For example, a silicide blocking layer that is or includes an oxide, a nitride, a high-k dielectric, the like, or a combination thereof may be formed over the semiconductor device, including over the exposed top surface (and any exposed sidewall surface) of the semiconductor region and the top surface of the isolation structure. A patterned mask (e.g., a hard mask, a photoresist layer, etc.) may then be formed over the silicide blocking layer. One or more removal processes (e.g., etching processes) may then be performed to remove portions of the silicide blocking layer to form the patterned silicide blocking layer. The patterned silicide blocking layer, in various examples, may be formed over a portion of the semiconductor region and a portion of the isolation structure. In various other examples, the patterned silicide blocking layer may be formed over the portion of the semiconductor region, over the entire isolation structure, and over a portion of an adjacent second semiconductor region. Other examples and configurations are possible based on design parameters.

After forming the patterned silicide blocking layer, a metal layer may be formed over the semiconductor device, including over the patterned silicide blocking layer and the semiconductor region. The placement of the patterned silicide blocking layer prevents formation of the metal layer on respective portions of the semiconductor region and the isolation structure (including the interface between the semiconductor region and the isolation structure) that are covered by the patterned silicide blocking layer. An annealing process may then be performed after which the silicide is formed as a result of the metal layer reacting with (or diffusing into) the semiconductor region. In other words, the metal atoms from the metal layer react with (or diffuse into) silicon from the semiconductor region, but not with the isolation structure or the patterned silicide blocking layer, to form silicide over the top surface of the semiconductor region (and not along the sidewall surfaces of the semiconductor region that is covered by the patterned silicide blocking layer). Accordingly, the patterned silicide blocking layer prevents the formation of silicide on portions of the semiconductor region at and/or around the interface between the semiconductor region and the isolation structure which may decrease leakage current in the semiconductor device.

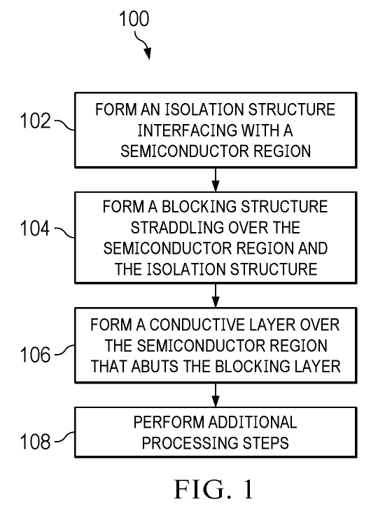

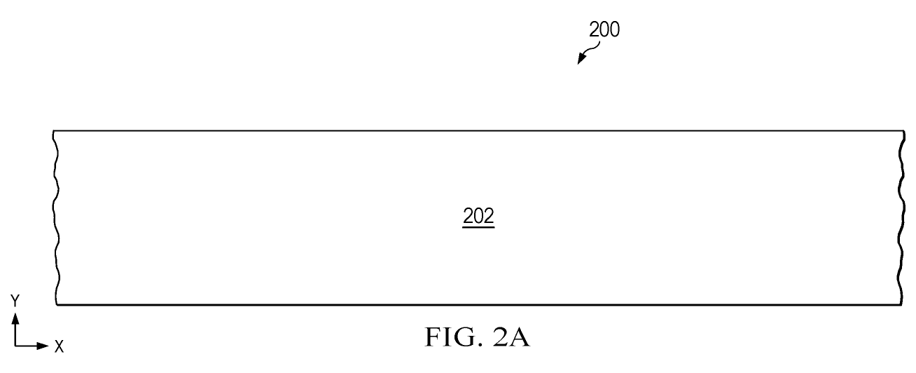

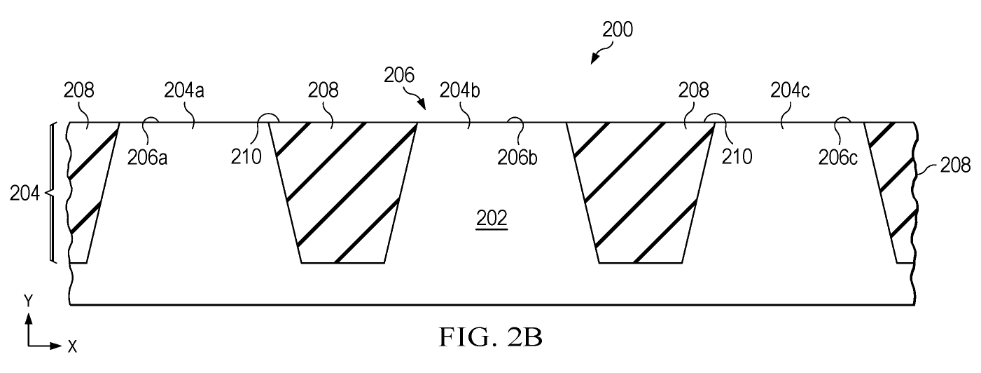

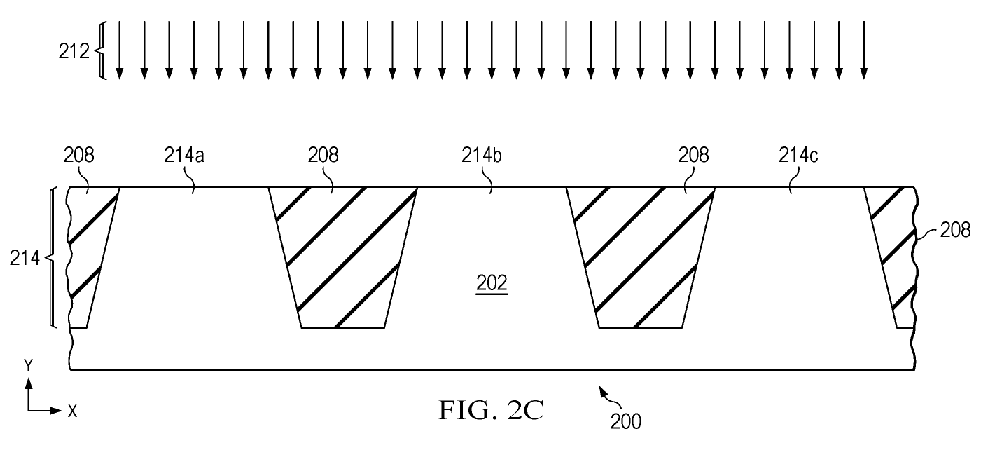

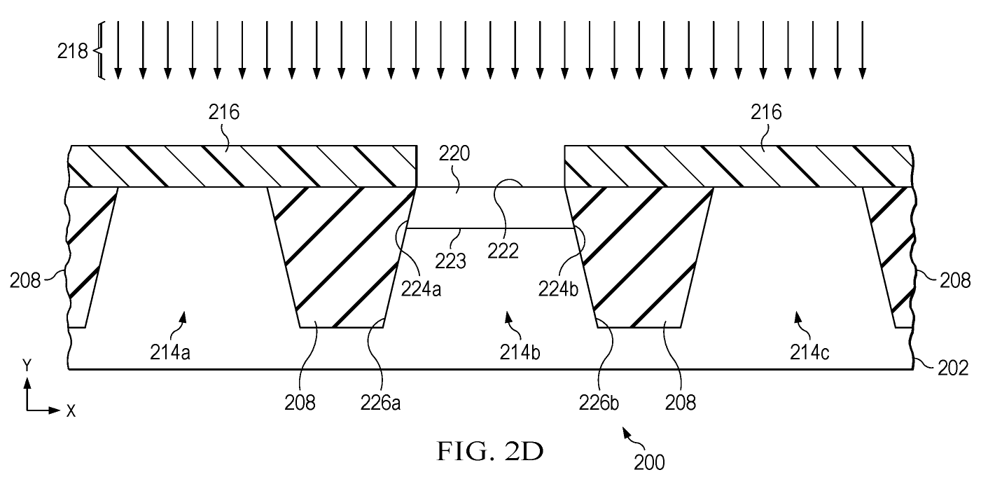

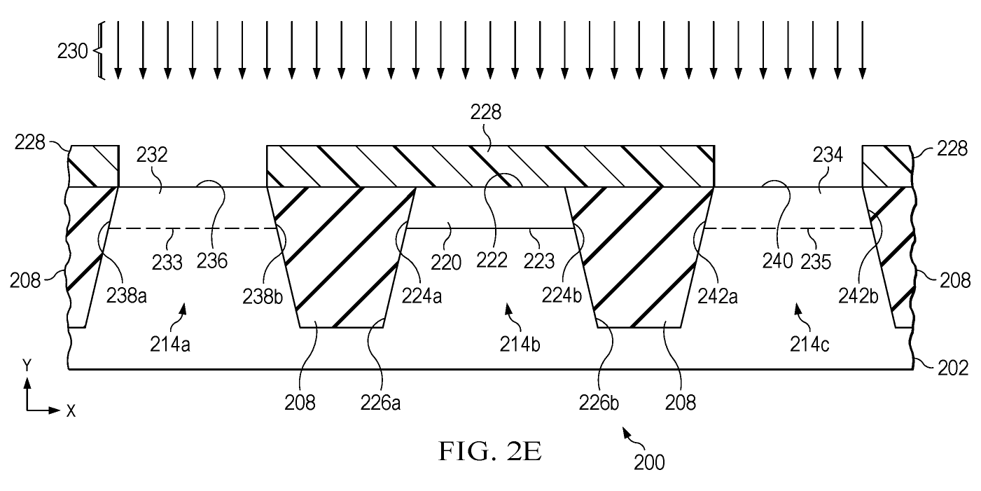

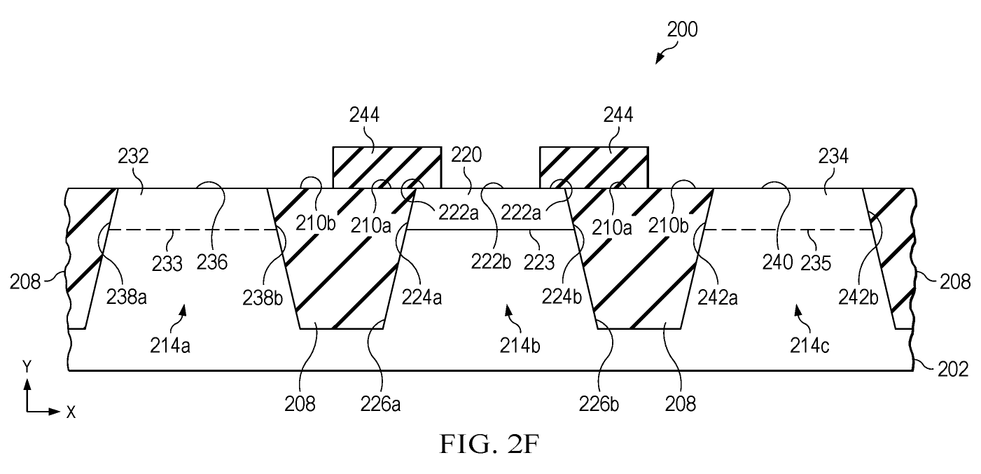

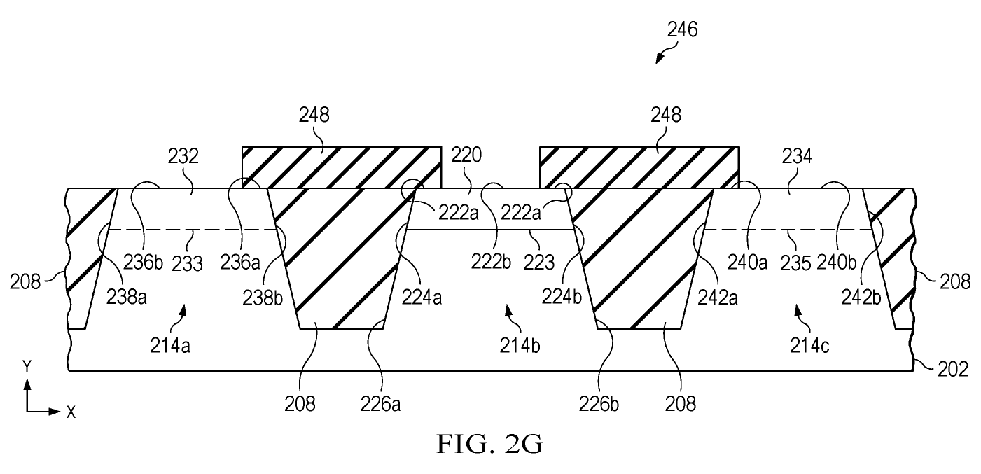

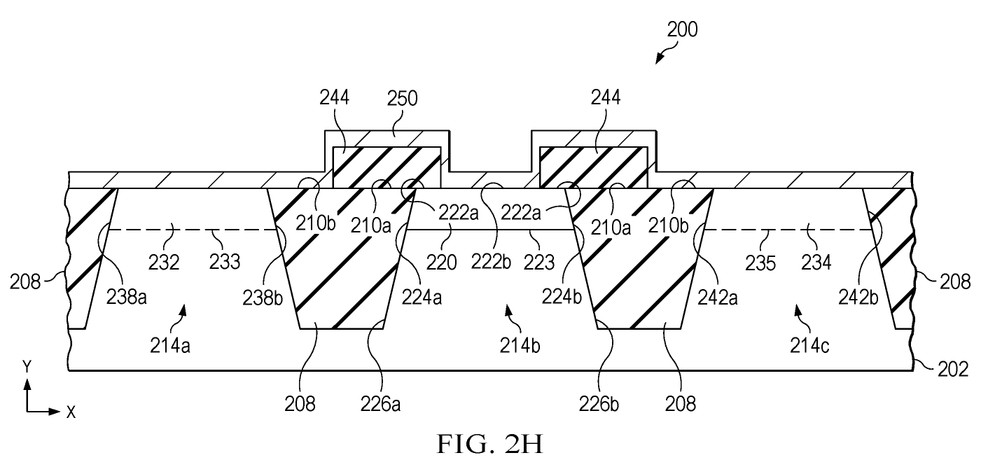

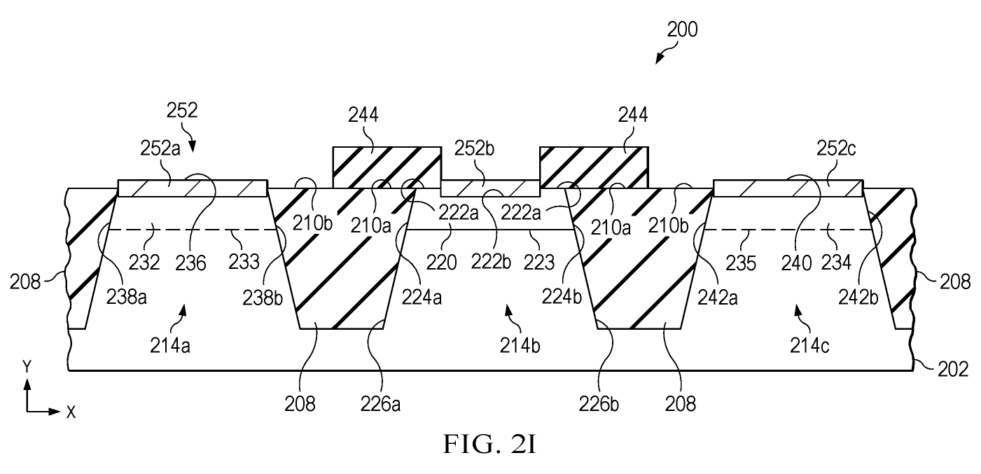

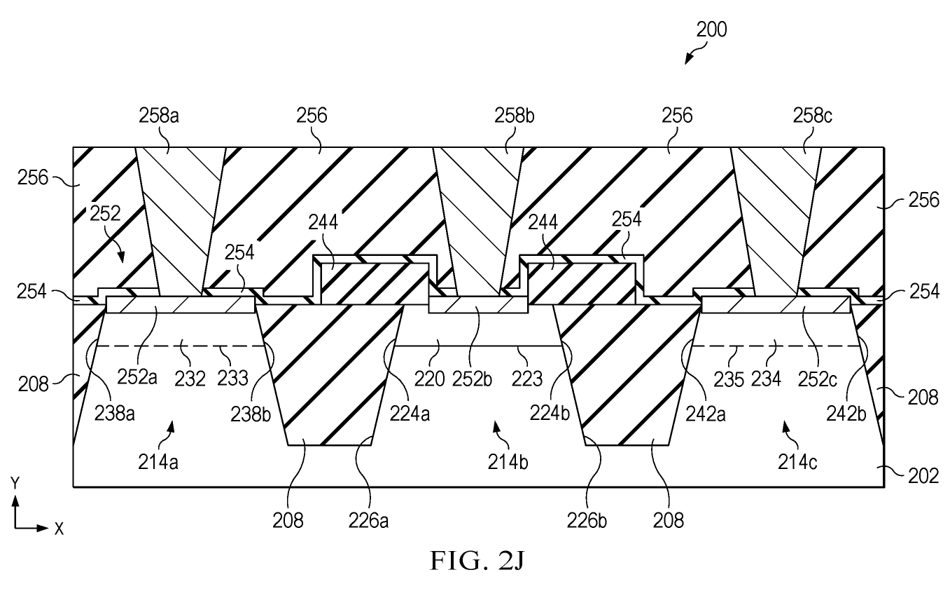

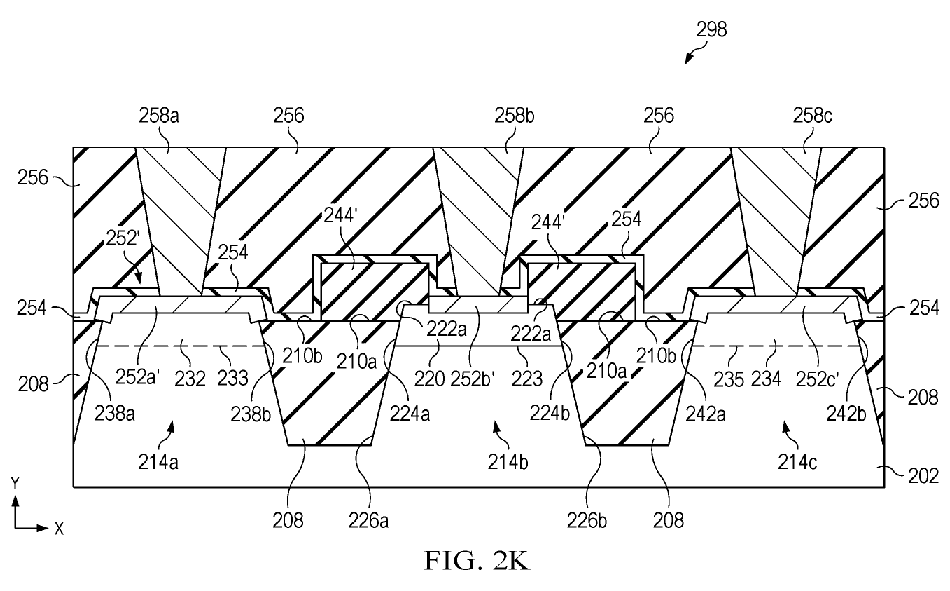

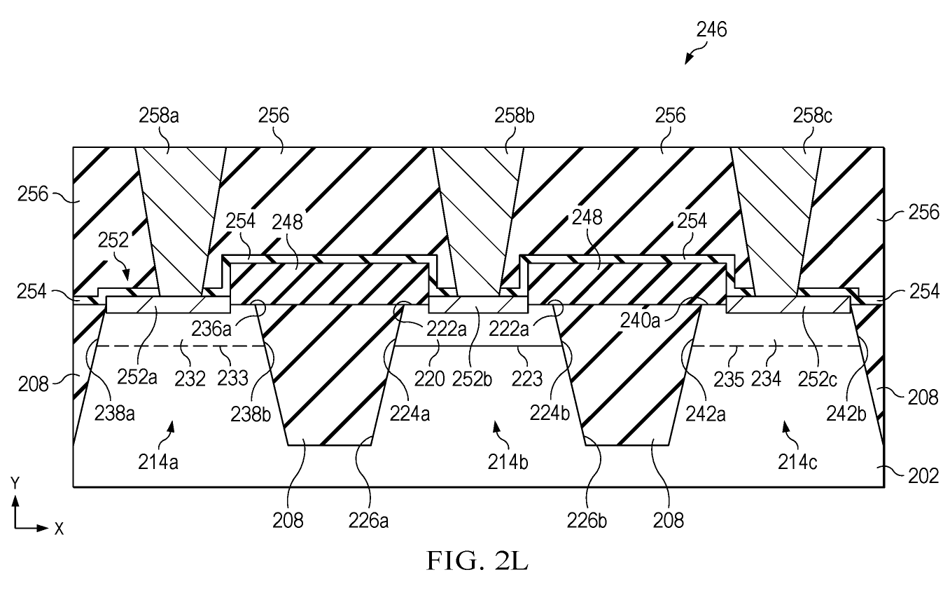

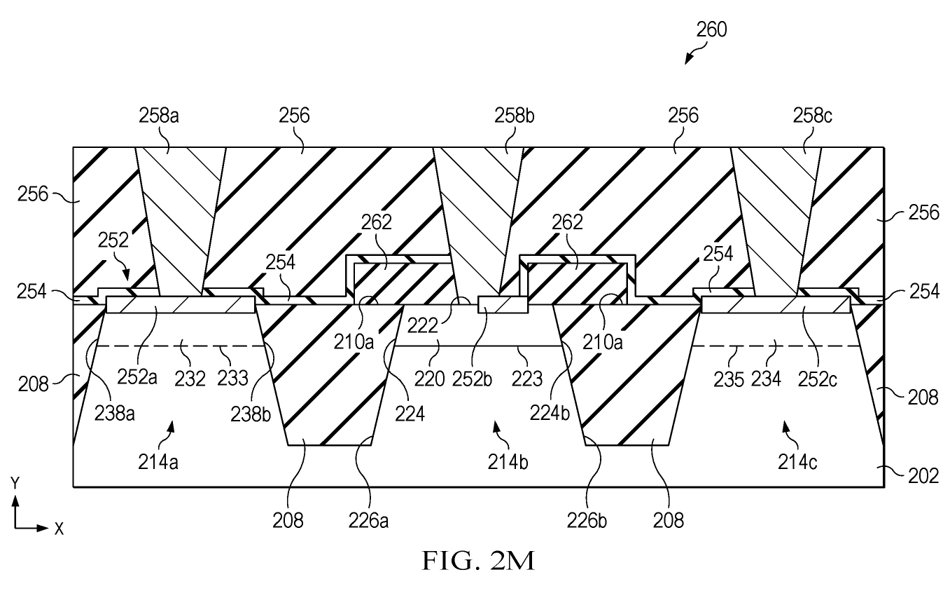

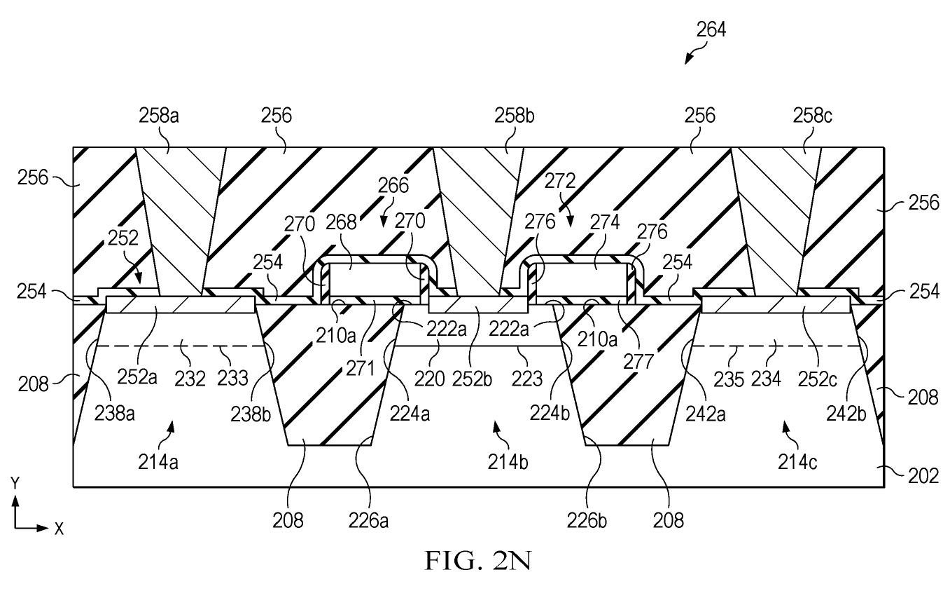

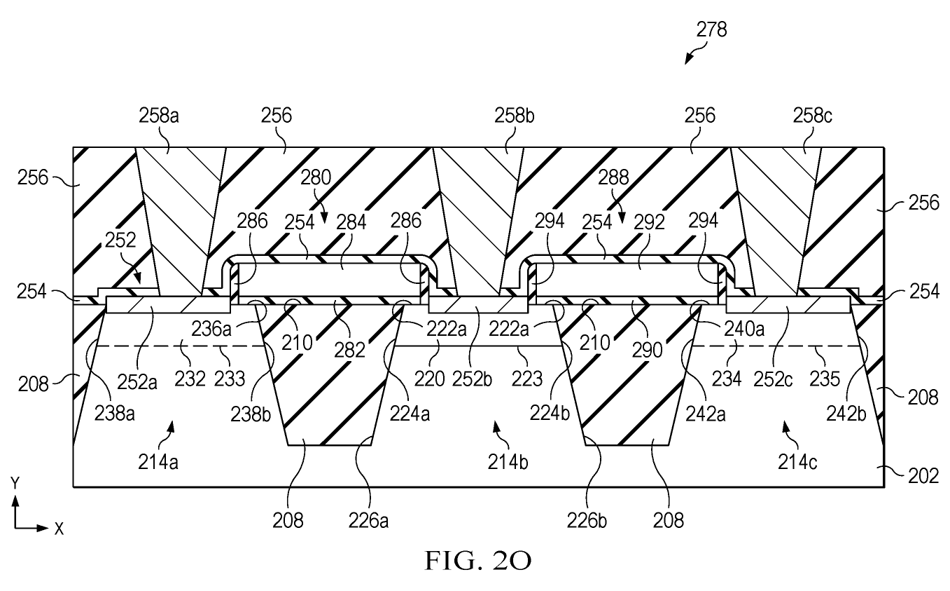

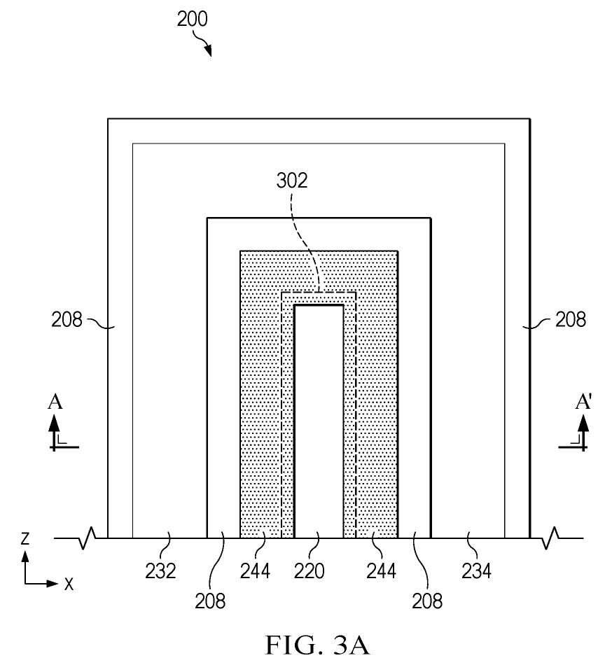

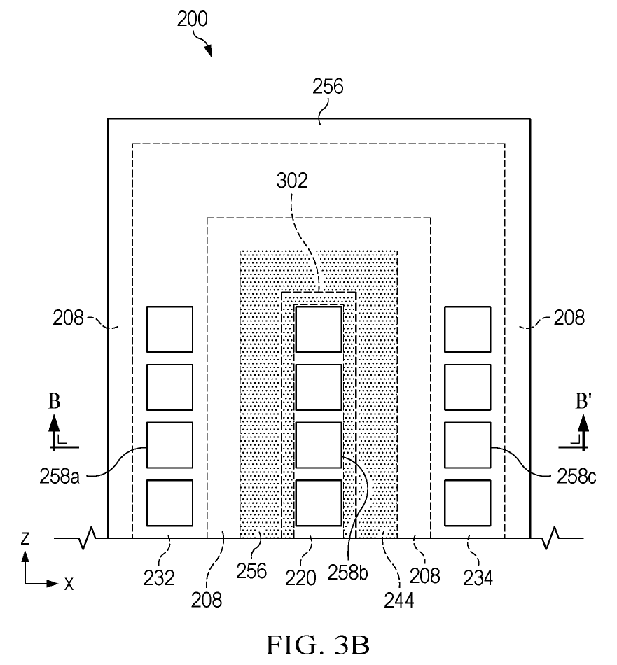

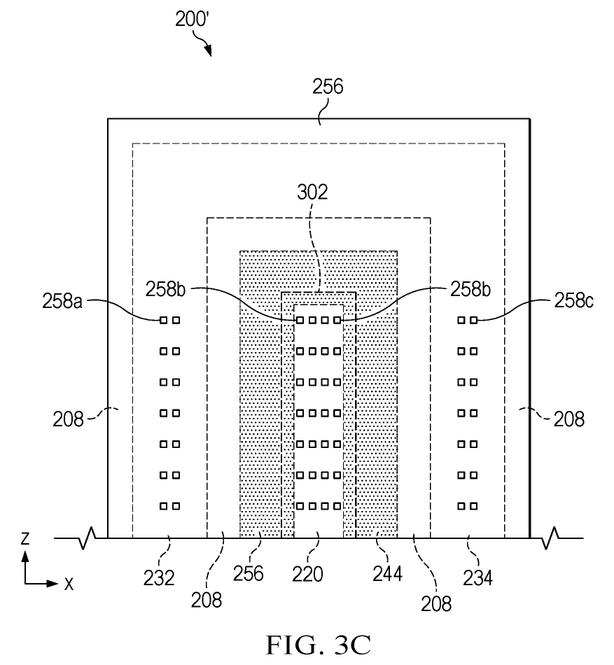

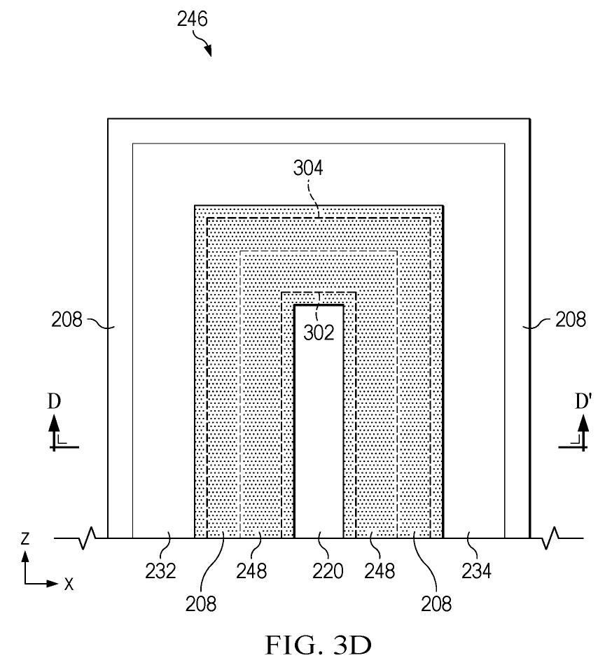

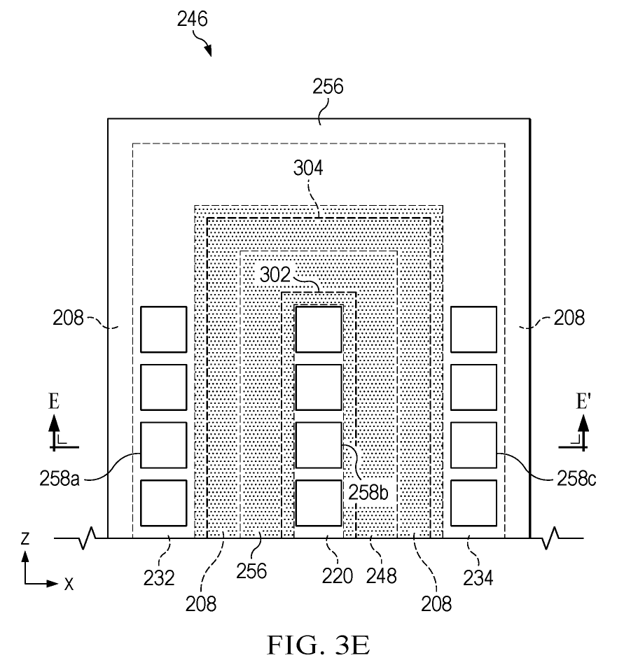

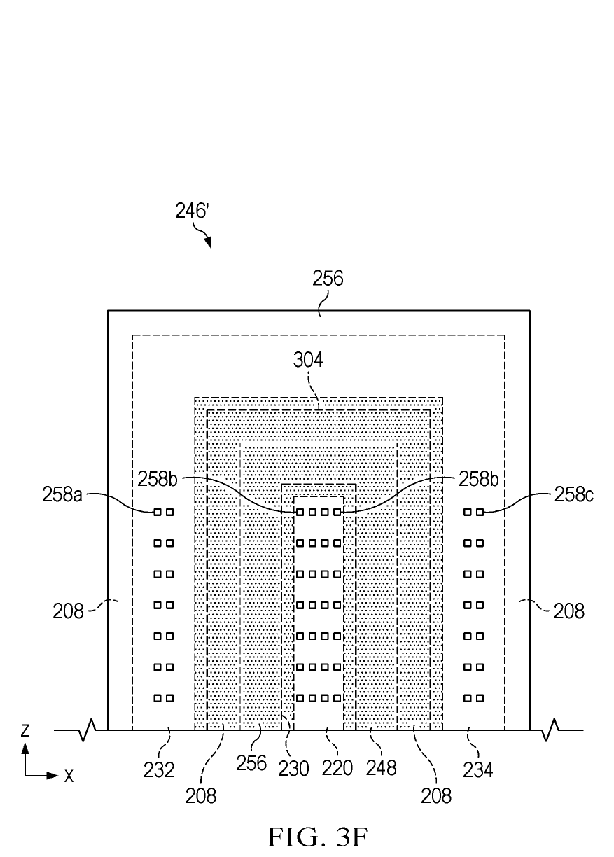

Referring now to FIG. 1, a flow diagram of a method 100 for forming a semiconductor device on a substrate is illustrated, in accordance with various examples of the present disclosure. In various examples, method 100 may be used to form a diode, a bipolar junction transistor (BJT), a field effect transistor (FET), and/or other semiconductor devices. In various examples, the semiconductor device formed using method 100 may be a diode including a p-n junction. Additional processes can be provided before, during, and after method 100. As described below, method 100 is described with reference to FIGS. 2A-2O and 3A-3F.

In that regard, FIGS. 2A-2O are diagrammatic cross-sectional views of example devices and FIGS. 3A-3F are top-down plan views of example devices at various stages of fabrication (such as those associated with method 100 of FIG. 1) according to various aspects of the present disclosure. The top-down views of FIGS. 3A-3F will be referred to at relevant points of the discussion of the cross-section views of FIGS. 2A-2O. Additional features can be added to the example devices and some features described below can be replaced, modified, or eliminated in other examples of the example devices.

At step 102 of FIG. 1, an isolation structure interfacing with a semiconductor region is formed. As shown in FIG. 2A, device 200 includes a semiconductor substrate 202. Semiconductor substrate 202, in various examples, may include one or more layers of silicon (Si), silicon germanium (SiGe), the like, or combinations thereof. For example, substrate 202 may include a silicon germanium layer disposed over a silicon layer. In other examples, substrate 202 may include a strained silicon layer disposed over a silicon germanium layer that is disposed over a silicon layer. In various other examples, one or more layers of semiconductor substrate 202 may include an n-type dopant, a p-type dopant, or combinations thereof. In various examples, semiconductor substrate 202 may include one or more epitaxially grown layers. In some examples, semiconductor substrate 202 may include an insulating layer, such that semiconductor substrate 202 may be considered a silicon-on-insulator (SOI) substrate.

As shown in FIG. 2B, and continuing with step 102, device 200 further includes semiconductor regions 204 having top surfaces 206 and isolation structures 208 having top surfaces 210. Semiconductor regions 204 includes a first semiconductor region 204a with a first top surface 206a, a second semiconductor region 204b with a second top surface 206b, a third semiconductor region 204c with a third top surface 206c. Semiconductor regions 204 may be formed by one or more processes. For example, a patterned photoresist layer may be formed over semiconductor substrate 202 such as by a photolithographic process. In various examples, the patterned photoresist layer may include a negative photoresist material or a positive photoresist material. The patterned photoresist layer may be patterned using one or more exposure and development processes. The patterned photoresist layer, in various examples, may be used as a mask to form one or more trenches in semiconductor substrate 202. In various examples, a patterned hard mask layer (e.g., an oxide layer, a nitride layer) may be formed in addition to, or instead of, the patterned photoresist layer.

In various examples, one or more etching processes may be used to form the one or more trenches using the patterned photoresist layer and/or a patterned mask layer. In various examples, the one or more etching processes may include a dry etch, a wet etch, or a combination thereof. The patterned photoresist layer may then be removed using one or more removal processes.

Isolation structures 208 (e.g., isolation regions, shallow trench isolation (STI) structures, deep trench isolation (DTI) structure, or the like) may be formed in the one or more trenches between semiconductor regions 204 using one or more processes. In various examples, the one or more processes may include a sputtering process, a deposition process, a chemical mechanical polish (CMP) process (e.g., removing excess dielectric material filling the trenches, an etching process (e.g., removing the hard mask layer, recessing a portion of isolation structures 208, etc.), the like, or a combination thereof. In various examples, after the one or more processes, isolation structures 208 may be formed to a height (e.g., in the positive y-direction) that is greater than the height of semiconductor regions 204. In other various examples, after the one or more processes, isolation structures 208 may be formed to a height (e.g., in the positive y-direction) that is equal to or less than the height of semiconductor regions 204. Isolation structures 208 may include or be an oxide, a nitride, a high-k dielectric material, the like, or a combination thereof. In some examples, when isolation structures 208 are formed of one or more dielectric materials these structures may be referred to as dielectric isolation structures.

In some examples, one or more planarization processes may be performed to planarize a top surface of device 200 including isolation structures 208 and semiconductor regions 204. In various examples, the one or more planarization processes may include a CMP process or the like. In various examples, as a result of statistical variations in the one or more processes used to form isolation structures 208, top surfaces 210 of isolation structures 208 may be (i) substantially planar to the top surfaces 206a-c of semiconductor regions 204a-c, (ii) recessed (e.g., lower) relative to the top surfaces 206a-c of semiconductor regions 204a-c, and/or (iii) elevated (e.g., higher) relative to the top surfaces 206a-c of semiconductor regions 204a-c. In various examples, this may be caused by variations in the removal rate (e.g., etch rate) between isolation structures 208 and semiconductor regions (e.g., first semiconductor region 204a, second semiconductor region 204b, and third semiconductor region 204c). Due to the difference in etch rate, later process steps may account for the relative differences (if any) between the respective top surfaces of the isolation structures 208 and semiconductor regions 204. Here, as shown in FIG. 2B for illustration purpose, top surfaces 210 of isolation structures 208 are depicted to be substantially planar with top surfaces 206a-c of semiconductor regions 204a-c.

In various other examples, isolation structures 208 may include combinations of one or more STI structures and/or DTI structures. In such examples, one or more process steps of forming isolation structures 208 (e.g., patterning of the DTI and/or STI) may affect the edges of isolation structures 208 (e.g., corner rounding). For example, the patterning process of a DTI structure may cause the edge of an STI structure adjacent a semiconductor region (e.g., semiconductor regions 204a-c) to be more rounded. This rounding effect may allow for increased silicide formation along a side edge (or sidewall surface) of the semiconductor region adjacent the STI structure. In other words, the rounding effect may allow for the silicide to wrap around the side edges of the semiconductor region. Such wrapping may lead to leakage current issues as described above. However, as described below, a patterned silicide blocking layer (e.g., blocking structure) may be formed over the interface between the semiconductor region and the STI structure before forming the silicide such that the patterned silicide blocking layer, in various examples, prevents the formation of silicide on portions of the semiconductor region at and/or around the interface between the semiconductor region and the STI structure which may decrease leakage current in the semiconductor device.

As shown in FIG. 2C, and continuing with step 102, a first implant process 212 may be performed on device 200. First implant process 212 may be performed using a first dopant type. In various examples, the first dopant type may be an n-type dopant or a p-type dopant. A first doped semiconductor region 214a, a second doped semiconductor region 214b, and a third doped semiconductor region 214c (also referred to as doped semiconductor regions 214) are formed as a result of first implant process 212. In various examples, first implant process may include one or more processes. In various examples, the one or more processes may include an ion implant process, an annealing process, the like, or a combination thereof.

For example, a first ion implant process may be performed to implant the first dopant type, either n-type or p-type, into first semiconductor region 204a, second semiconductor region 204b, and third semiconductor region 204c. In various examples, the n-type dopant may include phosphorus (P), antimony (Sb), arsenic (As), the like, or a combination thereof. In various examples, the p-type dopant may include boron (B), Indium (In), the like, or a combination thereof. In other examples, the semiconductor substrate 202 may have been previously doped (e.g., prior to forming the isolation structures 208). In such examples, first implant process 212 may be omitted.

In other examples, first semiconductor region 204a, second semiconductor region 204b, and third semiconductor region 204c may be formed by an epitaxial growth process (e.g., prior to forming the isolation structures 208). As described above, semiconductor substrate 202 may include one or more epitaxially grown layers. In such examples, the epitaxial growth process may include the first dopant such that first implant process 212 may be omitted. That is, in some examples, first doped semiconductor region 214a, second doped semiconductor region 214b, and third doped semiconductor region 214c are formed from patterning the one or more epitaxially grown layers of semiconductor substrate 202 without using first implant process 212. In other examples, the epitaxial grown semiconductor regions may be subjected to first implant process 212 to form first doped semiconductor region 214a, second doped semiconductor region 214b, and third doped semiconductor region 214c.

As shown in FIG. 2D, and continuing with step 102, a first patterned photoresist layer 216 is formed over device 200 and a second implant process 218 is performed to form a fourth doped semiconductor region 220. First patterned photoresist layer 216 covers first doped semiconductor region 214a, isolation structures 208, and third doped semiconductor region 214c while exposing second doped semiconductor region 214b. For example, a photoresist layer may be formed over device 200 including over isolation structures 208, first doped semiconductor region 214a, second doped semiconductor region 214b, and third doped semiconductor region 214c. An exposure and a removal process may be performed to form an opening in the photoresist layer that exposes second doped semiconductor region 214b, resulting in first patterned photoresist layer 216. Moreover, as shown, first doped semiconductor region 214a, second doped semiconductor region 214b, and third doped semiconductor region 214c interface with (or abut) isolation structures 208.

Second implant process 218 may be performed using a second dopant type. In various examples, the second dopant type has an opposite conductivity than the first dopant type and may be an n-type dopant or a p-type dopant. For example, when the first dopant type is an n-type dopant the second dopant type is a p-type dopant and when the first dopant type is a p-type dopant the second dopant type is an n-type dopant. Fourth doped semiconductor region 220 is formed as a result of second implant process 218.

Fourth doped semiconductor region 220 has a top surface 222 and opposing sidewall surfaces 224a-b, or side edges. Fourth doped semiconductor region 220 is formed over (e.g., in the positive y-direction) second doped semiconductor region 214b. Second doped semiconductor region 214b has opposing sidewall surfaces 226a-b, or side edges. In some examples, as shown, sidewall surfaces 226a-b are in line (e.g., extend along the same plane) with sidewall surfaces 224a-b of fourth doped semiconductor region 220. Moreover, as shown, fourth doped semiconductor region 220 (e.g., sidewall surfaces 224a-b) and second doped semiconductor region 214b (e.g., sidewall surfaces 226a-b) interface with (or abut) isolation structures 208.

In various examples, a p-n junction 223 (or n-p junction) may be formed between fourth doped semiconductor region 220 and second doped semiconductor region 214b, as indicated in FIG. 2D. In other words, the interface between fourth doped semiconductor region 220 and second doped semiconductor region 214b forms a p-n junction as a result of the difference in dopant types (e.g., opposite conductivity types) used in fourth doped semiconductor region 220 and second doped semiconductor region 214b.

As shown in FIG. 2E, and continuing with step 102, a second patterned photoresist layer 228 is formed over device 200 and a third implant process 230 is performed to form a fifth doped semiconductor region 232 and a sixth doped semiconductor region 234. Second patterned photoresist layer 228 covers fourth doped semiconductor region 220 and isolation structures 208 while exposing first doped semiconductor region 214a and third doped semiconductor region 214c. Second patterned photoresist layer 228 may be formed by similar processes as those described above with respect to first patterned photoresist layer 216 in FIG. 2D.

Third implant process 230 may be performed using the first dopant type (e.g., dopants with the same dopant type included in the first doped semiconductor region 214a and third doped semiconductor region 214c). In various examples, as described above, the first dopant type may be an n-type dopant or a p-type dopant. In various examples, the dopant used in third implant process 230 may be the same dopant as used in first implant process 212. In various examples, the dopant used in third implant process 230 may be different than the dopant used first implant process 212. Fifth doped semiconductor region 232 and sixth doped semiconductor region 234 are formed as a result of third implant process 230. Fifth doped semiconductor region 232 has opposing sidewall surfaces 238a-b, or side edges, and a top surface 236 extending therebetween. Sixth doped semiconductor region 234 has opposing sidewall surfaces 242a-b, or side edges, and a top surface 240 extending therebetween. Moreover, as shown, fifth doped semiconductor region 232 (e.g., sidewall surfaces 238a-b) and sixth doped semiconductor region 234 (e.g., sidewall surfaces 242a-b) interface with (or abut) isolation structures 208.

In some examples, fifth doped semiconductor region 232 and sixth doped semiconductor region 234 have a greater concentration of the first dopant type than first doped semiconductor region 214a and third doped semiconductor region 214c. The relatively greater concentration in the fifth doped semiconductor region 232 and sixth doped semiconductor region 234 facilitates reducing overall resistance of the device 200. As a result of the difference in the first dopant type concentration, there is an interface 233 between fifth doped semiconductor region 232 and first doped semiconductor region 214a and an interface 235 between sixth doped semiconductor region 234 and third doped semiconductor region 214c as depicted in FIG. 2E with dashed lines.

At step 104, a blocking structure is formed straddling over the semiconductor region and the isolation structure. For ease of understanding, reference is now made to FIGS. 2F and 3A where FIG. 2F is the cross-section view of FIG. 3A along the line A-A’ and FIG. 3A is the top-down view of device 200 during step 104. As shown in FIGS. 2F and 3A, device 200 includes a patterned silicide blocking layer 244 (e.g., blocking structure) straddling over (or overlapping) fourth doped semiconductor region 220 and isolation structures 208. Specifically, patterned silicide blocking layer 244 is formed over portions 222a of top surface 222 of fourth doped semiconductor region 220 and over portions 210a of top surfaces 210 of isolation structures 208. In other words, patterned silicide blocking layer 244 overlaps portions of both fourth doped semiconductor region 220 and isolation structures 208 such that an interface between fourth doped semiconductor region 220 and isolation structures 208 is covered by patterned silicide blocking layer 244. In various examples, as shown, portion 222b of top surface 222 of fourth doped semiconductor region 220, portions 210b of top surfaces 210 of isolation structures 208, top surface 236 of fifth doped semiconductor region 232, and top surface 240 of sixth doped semiconductor region 234 are exposed (e.g., uncovered) by patterned silicide blocking layer 244. FIG. 3A further shows the interface of isolation structures 208 and fourth doped semiconductor region 220 with a dashed line 302 for reference as portions of isolation structures 208 and fourth doped semiconductor region 220 are covered by patterned silicide blocking layer 244 as illustrated in FIG. 2F.

Moreover, in reference to FIGS. 2F and 3A, patterned silicide blocking layer 244 surrounds (e.g., laterally surrounds) an outer perimeter of fourth doped semiconductor region 220. That is, patterned silicide blocking layer 244 overlaps (or straddles) portions 210a of top surfaces 210 of isolation structures 208 and portions 222a of top surface 222 of fourth doped semiconductor region 220. As described in more detail below, such positioning (or orientation) of the patterned silicide blocking layer 244, in various examples, prevents the formation of silicide on portions of fourth doped semiconductor region 220 at and/or around the interface (e.g., dashed line 302 in FIG. 3A) between fourth doped semiconductor region 220 and isolation structures 208. Preventing the formation of silicide at and/or around the interface of isolation structures 208 and fourth doped semiconductor region 220 (e.g., dashed line 302 in FIG. 3A) may decrease leakage current in device 200.

Patterned silicide blocking layer 244 may comprise any material that resists or prevents the formation of silicide and is disposed on portions of fourth doped semiconductor region 220 where the formation of silicide would otherwise be undesirable (e.g., degrade device performance and/or reliability). In other words, patterned silicide blocking layer 244 may be or include any material that is suitable for blocking silicidation. In various example, patterned silicide blocking layer 244 may be or include an oxide, a nitride, a high-k dielectric material, the like, or a combination thereof. In various examples, the oxide may include silicon oxide. In various examples, the nitride may include silicon nitride and/or silicon oxynitride. In various examples, the high-k dielectric material may include hafnium dioxide, zirconium dioxide, or the like.

In various examples, patterned silicide blocking layer 244 may be or include similar materials as isolation structures 208. In various examples, patterned silicide blocking layer 244 may use the same material as isolation structures 208. In various examples, patterned silicide blocking layer 244 may use one or more different materials than isolation structures 208. Furthermore, the quality of the material (e.g., atomic composition, uniformity of the material, etc.) used for patterned silicide blocking layer 244 may be of a higher quality, the same quality, or a lower quality than the material of isolation structures 208. In examples where patterned silicide blocking layer 244 uses different material than isolation structures 208, either a different atomic composition or quality, the change from isolation structures 208 to patterned silicide blocking layer 244 may be detectable in the final device (e.g., using transmission electron microscopy (TEM), a scanning electron microscope (SEM), etc.).

In various examples, patterned silicide blocking layer 244 may be formed by first forming a dielectric material layer, such as those previously described, over device 200. A patterned mask layer may then be formed over the dielectric material layer. In various examples, the patterned mask layer may include photoresist, a hard mask material (e.g., TiN), the like, or a combination thereof. The dielectric material layer may then be etched using the patterned mask layer. Patterned silicide blocking layer 244 may be formed as a result of the etching process. Other processes may be used to form patterned silicide blocking layer 244.

In various other examples, patterned silicide blocking layer 244 may extend continuously from over fourth doped semiconductor region 220 to over fifth doped semiconductor region 232 and/or sixth doped semiconductor region 234. For ease of understanding, reference is now made to other such examples shown in FIGS. 2G and 3D. FIG. 2G is the cross-section view of FIG. 3D at the line D-D’ and FIG. 3D is the top-down view of a device 246 during step 104. Device 246 differs from device 200 with respect to the orientation (or configuration) of the patterned silicide blocking layer. As shown in FIGS. 2G and 3D, device 246 includes a patterned silicide blocking layer 248 formed on fourth doped semiconductor region 220 that extends over isolation structures 208 to both fifth doped semiconductor region 232 and sixth doped semiconductor region 234.

Specifically, patterned silicide blocking layer 248 is formed on portions 222a of top surface 222 of fourth doped semiconductor region 220, on top surfaces 210 of isolation structures 208, on a portion 236a of top surface 236 of fifth doped semiconductor region 232, and on a portion 240a of top surface 240 of sixth doped semiconductor region 234. In other words, patterned silicide blocking layer 248 overlaps (or straddles) portions of fourth doped semiconductor region 220, fifth doped semiconductor region 232, sixth doped semiconductor region 234, and isolation structures 208. In various examples, as shown, portion 222b of top surface 222 of fourth doped semiconductor region 220, portion 236b of top surface 236 of fifth doped semiconductor region 232, and portion 240b of top surface 240 of sixth doped semiconductor region 234 are exposed (e.g., uncovered) by patterned silicide blocking layer 248. FIG. 3D further shows interfaces between isolation structures 208 and fourth doped semiconductor region 220, fifth doped semiconductor region 232 and sixth doped semiconductor region 234 with dashed lines 302 and 304 for reference as portions of isolation structures 208, fourth doped semiconductor region 220, fifth doped semiconductor region 232 and sixth doped semiconductor region 234 are covered by patterned silicide blocking layer 248 as illustrated in FIG. 2G.

Moreover, as shown in FIG. 3D, patterned silicide blocking layer 248 surrounds (e.g., laterally surrounds) an outer perimeter of fourth doped semiconductor region 220 and inner perimeters of fifth doped semiconductor region 232 and sixth doped semiconductor region 234. That is, patterned silicide blocking layer 248 overlaps (or straddles) portions 222a of top surface 222 of fourth doped semiconductor region 220, top surfaces 210 of isolation structures 208, portion 236a of top surface 236 of fifth doped semiconductor region 232, and portion 240a of top surface 240 of sixth doped semiconductor region 234. As described in more detail below, such positioning (or orientation) of the patterned silicide blocking layer 248, in various examples, prevents the formation of silicide on portions of fourth doped semiconductor region 220 at and/or around the interface (e.g., dashed line 302 in FIG. 3D) between fourth doped semiconductor region 220 and isolation structures 208 which may decrease leakage current in device 246. Additionally, such positioning (or orientation) of the patterned silicide blocking layer 248, in various examples, prevents the formation of silicide on portions of fifth doped semiconductor region 232 and portions of sixth doped semiconductor region 234 at and/or around the interface (e.g., dashed line 304 in FIG. 3D) between fifth doped semiconductor region 232, sixth doped semiconductor region 234 and isolation structures 208.

Patterned silicide blocking layer 248 may be or include similar materials as those described above with respect to patterned silicide blocking layer 244 in FIG. 2F. Furthermore, patterned silicide blocking layer 248 may be formed using a similar process as that previously described for patterned silicide blocking layer 244 in FIG. 2F. Using a wider blocking structure (e.g., one that extends over isolation structures 208 to both fifth doped semiconductor region 232 and/or sixth doped semiconductor region 234) such as patterned silicide blocking layer 248 may allow for method 100 to be used on semiconductor devices having smaller feature sizes (e.g., smaller technology nodes, pitch sizes, or the like). As such, in various examples, patterned silicide blocking layer 248 may allow for method 100 to be performed using lower resolution photolithography processes to decrease costs and/or processing time.

In various examples, fourth doped semiconductor region 220, fifth doped semiconductor region 232, and sixth doped semiconductor region 234 may be formed after forming the patterned silicide blocking layer (e.g., patterned silicide blocking layer 244 or patterned silicide blocking layer 248). In that regard, the patterned silicide blocking layer may be formed as described above (e.g., over one or more of first, second, or third doped semiconductor regions 214a, 214b, 214c and isolation structures 208). First patterned photoresist layer 216 may then be formed including over the patterned silicide blocking layer. Second implant process 218 may then be performed, as described above, to form fourth doped semiconductor region 220. Thereafter, first patterned photoresist layer 216 is removed and subsequently second patterned photoresist layer 228 may be formed including over the patterned silicide blocking layer. Third implant process 230 may then be performed, as described above, to form fifth doped semiconductor region 232 and sixth doped semiconductor region 234. Accordingly, the steps of method 100 may be performed in a different order while remaining within the scope of this disclosure.

At step 106, a conductive layer (e.g., silicide layer) is formed over the semiconductor region that abuts the blocking layer. Resuming method 100 from FIG. 2F where patterned silicide blocking layer 244 is formed over device 200, as shown in FIG. 2H, a metal layer 250 is formed over device 200. Metal layer 250 may be or include titanium (Ti), nickel (Ni), cobalt (Co), tungsten (W), molybdenum (Mo), platinum (Pt), chromium (Cr), the like, or a combination thereof. Metal layer 250 may be formed over fourth doped semiconductor region 220, fifth doped semiconductor region 232, sixth doped semiconductor region 234, patterned silicide blocking layer 244, and isolation structures 208. However, as shown, patterned silicide blocking layer 244 prevents the formation of metal layer 250 on portions 222a of top surface 222 of fourth doped semiconductor region 220 and on portions 210a of top surfaces 210 of isolation structures 208. As described in more detail below, because patterned silicide blocking layer 244 prevents metal layer 250 from being formed on portions 222a of the top surface 222 of fourth doped semiconductor region 220 silicide is prevented from being formed in these areas including at and/or around the interface between fourth doped semiconductor region 220 and isolation structures 208.

As shown in FIG. 2H, metal layer 250 may be formed over horizontal surfaces (e.g., along the x-axis) and vertical surfaces (e.g., along the y-axis) of device 200. For example, metal layer 250 may be formed over top surfaces of isolation structures 208, fourth doped semiconductor region 220, fifth doped semiconductor region 232, sixth doped semiconductor region 234, and patterned silicide blocking layer 244 and over sidewall surfaces of patterned silicide blocking layer 244. In various other examples, metal layer 250 may further be formed over sidewall surfaces of fifth doped semiconductor region 232 and/or sixth doped semiconductor region 234 (as described below in reference to FIG. 2K). However, as described above, patterned silicide blocking layer 244 blocks formation of metal layer 250 on portions of fourth doped semiconductor region 220 at and/or around the interface (e.g., dashed line 302 in FIG. 3A) between fourth doped semiconductor region 220 and isolation structures 208.

In various examples, metal layer 250 may be thicker in a first direction (e.g., the y-direction) than in a second direction (e.g., the x-direction). In other words, metal layer 250 may be thicker on horizontal surfaces of device 200 (e.g., top surface of isolation structures 208, top surface of patterned silicide blocking layer 244, etc.) than on vertical surfaces (e.g., sidewall surfaces of patterned silicide blocking layer 244, etc.).

Metal layer 250 may be formed over device 200 using one or more processes. In various examples, the one or more processes may include chemical vapor deposition (CVD), physical vapor deposition (PVD), the like, or a combination thereof. In various examples, the PVD processes may include sputtering, evaporation, the like, or a combination thereof. In various examples, the CVD processes may include low-pressure CVD (LPCVD), plasma-enhance CVD (PECVD), atomic layer deposition (ALD), the like, or a combination thereof.

As shown in FIG. 2I, and continuing with step 106, a silicide layer 252 (e.g., conductive layer) is formed from the reaction of the underlying doped semiconductor regions (e.g., 220, 232, and 234) with metal layer 250. In various examples, a silicidation process, a salicidation process, and/or other suitable processes may be performed to form silicide layer 252. In various examples, an annealing process may be performed to cause metal layer 250 to react with (or diffuse into) fourth doped semiconductor region 220, fifth doped semiconductor region 232, and sixth doped semiconductor region 234. That is, the metal atoms from the metal layer 250 react with (or diffuse into) silicon from the various doped semiconductor regions to form silicide layer 252. The portions of metal layer 250 (e.g., titanium (Ti), nickel (Ni), cobalt (Co), tungsten (W), molybdenum (Mo), platinum (Pt), and chromium (Cr), etc.) that are disposed on fourth, fifth, and sixth doped semiconductor regions 220, 230, 232 may be consumed and converted into silicide layer 252 (e.g., TiₓSi_{y}, NiₓSi_{y}, CoₓSi_{y}, WₓSi_{y}, MoₓSi_{y}, PtₓSi_{y}, CrₓSi_{y}, etc.) as a result of the annealing process. In various examples, a removal process may then be performed to remove the unreacted portions (if any) of metal layer 250 from over device 200 (e.g., remove unreacted metal layer 250 from over isolation structures 208 and patterned silicide blocking layer 244).

As shown, silicide layer 252 includes segments 252a, 252b and 252c (e.g., conductive layers), respectively formed over fifth doped semiconductor region 232, fourth doped semiconductor region 220, and sixth doped semiconductor region 234. In that regard, as shown, patterned silicide blocking layer 244 prevents the formation of silicide over portions 222a of top surface 222 of fourth doped semiconductor region 220. In other words, such positioning (or orientation) of patterned silicide blocking layer 244, in various examples, prevents the formation of silicide on portions of fourth doped semiconductor region 220 at and/or around the interface (e.g., dashed line 302 in FIG. 3A) between fourth doped semiconductor region 220 and isolation structures 208. As such, patterned silicide blocking layer 244 prevents the formation of silicide along sidewall surfaces 224a-b of fourth doped semiconductor region 220.

Instead, segment 252b of silicide layer 252 is formed only on portion 222b of top surface 222 of fourth doped semiconductor region 220 that was exposed (e.g., uncovered/not covered) by patterned silicide blocking layer 244. Also, in some examples, segment 252b of silicide layer 252 abuts (e.g., physically contacts, interfaces, or the like) patterned silicide blocking layer 244. Moreover, as shown, segment 252b of silicide layer 252 does not extend along sidewall surfaces 224a-b of fourth doped semiconductor region 220. By not extending along sidewall surfaces 224a-b of fourth doped semiconductor region 220 leakage current in device 200 may be decreased or prevented. This is because inadvertent leakage current may occur when silicide layer 252 extends along sidewall surfaces 224a-b (or wrap around the edges) of fourth doped semiconductor region 220 towards second doped semiconductor region 214b (e.g., p-n junction 223 between fourth doped semiconductor region 220 and second doped semiconductor region 214b).

In contrast, in various examples, segments 252a and 252c of silicide layer 252 extend to the interface between isolation structures 208 and fifth doped semiconductor region 232 and/or sixth doped semiconductor region 234. As described above, the stress caused by the interface between the different materials forming isolation structures 208, fifth doped semiconductor region 232 and/or sixth doped semiconductor region 234 may allow for formation of silicide along sidewall surfaces 238a-b, 242a-b (or wrap around the edges) of fifth doped semiconductor region 232 and sixth doped semiconductor region 234, respectively. This is because patterned silicide blocking layer 244 was not formed over (e.g., overlapping or straddling) fifth doped semiconductor region 232 and sixth doped semiconductor region 234. Thus, segments 252a and 252c of silicide layer 252 may extend along sidewall surfaces 238a-b, 242a-b and the top surfaces 236, 240 of fifth doped semiconductor region 232 and sixth doped semiconductor region 234, respectively. However, as shown, because top surfaces 210 of isolation structures 208 were substantially coplanar with top surfaces 236, 240 of fifth doped semiconductor region 232 and sixth doped semiconductor region 234, respectively, prior to step 106, segments 252a and 252c of silicide layer 252 are limited (or inhibited) from extending too far along sidewall surfaces 238a-b, 242a-b of fifth doped semiconductor region 232 and sixth doped semiconductor region 234, respectively.

Moreover, any extension of segments 252a and 252c of silicide layer 252 along sidewall surfaces 238a-b, 242a-b of fifth doped semiconductor region 232 and sixth doped semiconductor region 234 has minimal (or no) impact on device performance and/or reliability. For example, unlike the p-n junction formed at the interface between fourth doped semiconductor region 220 and second doped semiconductor region 214b, the interfaces 233, 235 between fifth doped semiconductor region 232 and first doped semiconductor region 214a or sixth doped semiconductor region 234 and third doped semiconductor region 214c do not form p-n junctions. Instead, as discussed above in various examples, first doped semiconductor region 214a, third doped semiconductor region 214c, fifth doped semiconductor region 232, and sixth doped semiconductor region 234 all have the same conductivity type with fifth doped semiconductor region 232 and sixth doped semiconductor region 234 having greater dopant concentrations than first doped semiconductor region 214a and third doped semiconductor region 214c, respectively. Thus, the extension of segments 252a and 252c of silicide layer 252 along sidewall surfaces 238a-b, 242a-b of fifth doped semiconductor region 232 and/or sixth doped semiconductor region 234 may not lead to leakage current issues.

At step 108, additional processing steps may be performed. As shown in FIGS. 2J and 3B, additional processing steps of device 200 are completed. FIG. 3B shows a top-down view of device 200 and FIG. 2J shows a cross-section view of device 200 along the line B-B’. As shown in FIG. 2J, a liner layer 254, a dielectric layer 256, and contacts 258a-c are formed over device 200. Specifically, liner layer 254, also referred to as a pre-metal dielectric (PMD) liner, is formed over isolation structures 208, patterned silicide blocking layer 244, and silicide layer 252. Dielectric layer 256, also referred to as an interlayer dielectric (ILD), is formed over liner layer 254. Contacts 258a-c, including a first contact 258a, a second contact 258b, and a third contact 258c are formed through dielectric layer 256 and liner layer 254 and land on silicide layer 252. FIG. 3B shows dielectric layer 256 formed over device 200 with contacts 258a-c formed therethrough (additional horizontal rows of contacts (e.g., along x-direction) are also shown but not labeled for ease of understanding). FIG. 3B further shows isolation structures 208 and patterned silicide blocking layer 244 with dashed outlines for reference as both isolation structures 208 and patterned silicide blocking layer 244 are covered by silicide layer 252, liner layer 254, and dielectric layer 256 as illustrated in FIG. 2J. For ease of understanding, FIG. 3B focuses on isolation structures 208, patterned silicide blocking layer 244, fourth doped semiconductor region 220, fifth doped semiconductor region 232, and sixth doped semiconductor region 234 which are shown in dashed lines under dielectric layer 256.

Liner layer 254 may include one or more layers of dielectric material. The one or more layers of dielectric material of liner layer 254 may include oxide, nitride and/or carbide materials such as silicon oxide, silicon nitride, silicon oxy-nitride, and/or silicon carbide, the like, or a combination thereof. The use of the term silicon oxide throughout this disclosure includes materials such as silicon monoxide (SiO) and/or silicon dioxide (SiO₂) and/or a non-stoichiometric mixture of the two.

Dielectric layer 256 (or interlayer dielectric (ILD)) may be a single dielectric layer or may include multiple dielectric layers of a same dielectric material or different dielectric materials. In various examples, dielectric layer 256 may include silicon nitride, a silicon oxide-based material (such as a phosphosilicate glass (PSG), borophosphosilicate glass (BPSG), or a tetraethyl orthosilicate (TEOS) oxide), polytetrafluoroethylene, or the like.

Contacts 258a-c may be formed through dielectric layer 256 and liner layer 254 to land on segments 252a, 252b and 252c of silicide layer 252 disposed over fifth doped semiconductor region 232, fourth doped semiconductor region 220, and sixth doped semiconductor region 234, respectively. In various examples, contacts 258a-c may each include (i) one or more metal-barrier and/or adhesion layers (e.g., titanium nitride (TiN), tantalum nitride (TaN), the like, or a combination thereof) conformally in a respective opening through dielectric layer 256 and liner layer 254 and (ii) a fill metal (e.g., aluminum (Al), copper (Cu), tungsten (W), the like, or a combination thereof) over and/or on the metal-barrier and/or adhesion layer(s). Also, one or more metal lines may be formed over and on (and electrically connected to) contacts 258-c. The metal lines may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s).

In other examples, device 200 may include more contacts in each horizontal row (e.g., along x-direction) than shown in FIGS. 2J and 3B. In that regard, for ease of understanding reference is now made to FIG. 3C which illustrates a top-down view of a device 200’ that includes similar components to device 200 described above in FIG. 3B. In various examples, each of first contact 258a, second contact 258b, and third contact 258c may now include a plurality of contacts (e.g., 2, 3, 4, etc.). For example, first contact 258a and third contact 258c may each include two contacts, as shown in FIG. 3C. As another example, second contact 258b may include four contacts, as shown in FIG. 3C. FIG. 3C illustrates additional horizontal rows of contacts (e.g., along x-direction) but are not labeled for ease of understanding. In various examples, design and manufacture of device 200’ may include more than one discrete metal contact for each of first, second, and third contacts 258a, 258b, 258c. In other words, first contact 258a, second contact 258b, and/or third contact 258c may include one or more discrete metal contacts depending on the design requirements for a given semiconductor device.

As described above, in various examples, because of the one or more processes variations used to form isolation structures 208, top surfaces 210 of isolation structures 208 may be recessed (e.g., lower) relative to the top surfaces 222, 236 and 240 of fourth doped semiconductor region 220, fifth doped semiconductor region 232, and/or sixth doped semiconductor region 234, respectively. In such examples, portions of sidewall surfaces 224a-b (e.g., side edges) of fourth doped semiconductor region 220, portions of sidewall surfaces 236a-b of fifth doped semiconductor region 232, and portions of sidewall surfaces 242a-b of sixth doped semiconductor region 234 may be exposed after step 102 of method 100.

Because of the p-n junction 223 formed between fourth doped semiconductor region 220 and second doped semiconductor region 214b, silicide formation along exposed sidewall surfaces 224a-b of fourth doped semiconductor region 220 may lead to leakage current issues deleteriously effecting a device’s reliability and performance. To prevent such leakage current issues, as described further below in reference to FIG. 2K, a patterned silicide blocking layer (e.g., blocking structure) may be formed during step 104 over the interface between fourth doped semiconductor region 220 and isolation structures 208, including along sidewall surfaces 224a-b of fourth doped semiconductor region 220, before forming the silicide layer at step 106 of method 100.

In that regard, FIG. 2K illustrates a device 298 after processing steps 106 and 108 of method 100. As shown, device 298 is formed such that top surfaces 210 of isolation structures 208 are recessed (e.g., lower in the negative y-direction) relative to the top surfaces 222, 236 and 240 of fourth doped semiconductor region 220, fifth doped semiconductor region 232, sixth doped semiconductor region 234, respectively. For ease of understanding and brevity, device 298 is similar to device 200 except as note herein. Descriptions of similar features may not be repeated below.

As shown, patterned silicide blocking layer 244’ is formed straddling (or overlapping) over portions of fourth doped semiconductor region 220 and isolation structures 208. Specifically, patterned silicide blocking layer 244’ is formed over portions 222a of top surface 222 and along portions of sidewall surfaces 224a-b of fourth doped semiconductor region 220 and over portions 210a of top surfaces 210 of isolation structures 208. In other words, patterned silicide blocking layer 244’ is disposed along each of the sidewall surfaces 224a-b of fourth doped semiconductor region 220 while overlapping portions 210a of top surfaces 210 of isolation structures 208 and portions 222a of top surface 222 of fourth doped semiconductor region 220. In various examples, as shown, patterned silicide blocking layer 244’ does not cover portion 222b of top surface 222 of fourth doped semiconductor region 220, portions 210b of top surfaces 210 of isolation structures 208, top surface 236 and portions of sidewall surfaces 238a-b of fifth doped semiconductor region 232, and top surface 240 and portions of sidewall surfaces 242a-b of sixth doped semiconductor region 234.

As shown, silicide layer 252’ includes segments 252a’, 252b’ and 252c’ (e.g., conductive layers), respectively formed over fifth doped semiconductor region 232, fourth doped semiconductor region 220, and sixth doped semiconductor region 234. In that regard, because patterned silicide blocking layer 244’ prevents the formation of silicide along sidewall surfaces 224a-b of fourth doped semiconductor region 220, segment 252b’ of silicide layer 252’ is formed only on portion 222b of top surface 222 of fourth doped semiconductor region 220 that was exposed (e.g., uncovered/not covered) by patterned silicide blocking layer 244’. Also, in some examples, segment 252b’ of silicide layer 252 abuts (e.g., physically contacts, interfaces, or the like) patterned silicide blocking layer 244’. Moreover, as shown, segment 252b’ of silicide layer 252’ does not extend along sidewall surfaces 224a-b of fourth doped semiconductor region 220. By not extending along sidewall surfaces 224a-b of fourth doped semiconductor region 220 (e.g., having the segment 252b’ of silicide layer 252 confined (or contained) away from the sidewall surfaces 224a-b), leakage current in device 298 may be decreased or prevented. This is because inadvertent leakage current may occur when silicide layer 252’ extends along sidewall surfaces 224a-b (or wrap around the edges) of fourth doped semiconductor region 220 towards second doped semiconductor region 214b (e.g., p-n junction 223 between fourth doped semiconductor region 220 and second doped semiconductor region 214b).

In contrast, segments 252a’ and 252c’ of silicide layer 252’ extend to and along sidewall surfaces 238a-b, 242a-b (or wrap around the edges) of fifth doped semiconductor region 232 and sixth doped semiconductor region 234, respectively. This is because patterned silicide blocking layer 244’ was not formed over fifth doped semiconductor region 232 and sixth doped semiconductor region 234. Thus, segments 252a’ and 252c’ of silicide layer 252’ extend along sidewall surfaces 238a-b, 242a-b and the top surfaces 236, 240 of fifth doped semiconductor region 232 and sixth doped semiconductor region 234, respectively. Moreover, because segments 252a’ and 252c’ of silicide layer 252 extend along sidewall surfaces 238a-b, 242a-b of fifth doped semiconductor region 232 and sixth doped semiconductor region 234, respectively, these segments may extend closer to semiconductor substrate 202 than segment 252b’ of silicide layer 252’.

In other examples, as described above with respect to FIG. 2G, patterned silicide blocking layer 248 may extend continuously from over fourth doped semiconductor region 220 to over fifth doped semiconductor region 232 and/or sixth doped semiconductor region 234 in device 246. In such examples, processing steps 106 and 108 of method 100 are similar to those described above with respect to FIGS. 2H-2I except with respect to the orientation (or configuration) of the silicide blocking layer in those figures. For brevity purposes and ease of understanding, FIGS. 2L and 3E illustrate device 246 after processing steps 106 and 108 of method 100 where patterned silicide blocking layer 248 extends from over fourth doped semiconductor region 220 to over fifth doped semiconductor region 232 and sixth doped semiconductor region 234 in device 246.

In that regard, FIG. 2L shows a cross-section view of device 246 along the line E-E’ of FIG. 3E which shows a top-down view of device 246. As shown in FIG. 2L, and similar to FIG. 2J, device 246 includes liner layer 254 formed over isolation structures 208, silicide layer 252, and patterned silicide blocking layer 248. Dielectric layer 256 is formed over liner layer 254 and contacts 258a-c are formed through dielectric layer 256 and liner layer 254 and onto silicide layer 252, as described above in FIG. 2J. FIG. 3E further shows isolation structures 208 and patterned silicide blocking layer 248 with dashed outlines for reference as both isolation structures 208 and patterned silicide blocking layer 248 are covered by silicide layer 252, liner layer 254, and dielectric layer 256. For ease of understanding, FIG. 3E focuses on isolation structures 208, patterned silicide blocking layer 248, fourth doped semiconductor region 220, fifth doped semiconductor region 232, and sixth doped semiconductor region 234 which are shown in dashed lines under dielectric layer 256.

In contrast to patterned silicide blocking layer 244 described in reference to FIGS. 2F and 2H-2J, patterned silicide blocking layer 248 further covers portions of fifth doped semiconductor region 232 and sixth doped semiconductor region 234, preventing formation of silicide layer 252 on the covered portions. As shown in FIG. 2L, patterned silicide blocking layer 248 prevents the formation of silicide layer 252 on sidewall surfaces 224a-b and portions 222a of top surface 222 of fourth doped semiconductor region 220, on sidewall surface 238b and a portion 236a of top surface 236 of fifth doped semiconductor region 232, and on sidewall surface 242a and a portion 240a of top surface 240 of sixth doped semiconductor region 234.

In that regard, as shown in FIG. 2L, silicide layer 252 includes segments 252a, 252b, and 252c (e.g., conductive layers) formed over fifth doped semiconductor region 232, fourth doped semiconductor region 220, and sixth doped semiconductor region 234, respectively. As shown, patterned silicide blocking layer 248 prevents the formation of silicide over portions 222a of top surface 222 of fourth doped semiconductor region 220. In other words, such positioning (or orientation) of patterned silicide blocking layer 248, in various examples, prevents the formation of silicide on portions of fourth doped semiconductor region 220 at and/or around the interface (e.g., dashed line 302 in FIG. 3D) between fourth doped semiconductor region 220 and isolation structures 208. As such, patterned silicide blocking layer 248 prevent the formation of silicide along sidewall surfaces 224a-b of fourth doped semiconductor region 220.

Instead, segment 252b of silicide layer 252 is formed only on portion 222b of top surface 222 of fourth doped semiconductor region 220 that was exposed (e.g., uncovered/not covered) by patterned silicide blocking layer 248. Because patterned silicide blocking layer 248 prevents the formation of silicide along sidewall surfaces 224a-b of fourth doped semiconductor region 220, leakage current in device 200 may be decreased or prevented. This is because inadvertent leakage current may occur when silicide layer 252 extends along sidewall surfaces 224a-b (or wrap around the edges) of fourth doped semiconductor region 220 towards second doped semiconductor region 214b (e.g., p-n junction 223 between fourth doped semiconductor region 220 and second doped semiconductor region 214b).

Moreover, patterned silicide blocking layer 248 formed over portions 236a, 240a of fifth doped semiconductor region 232 and sixth doped semiconductor region 234, respectively, prevent silicide layer 252 from being formed thereon. In other words, segments 252a and 252c of silicide layer 252 do not extend to the interface (e.g., dashed line 304 in FIG. 3D) between isolation structures 208 and either fifth doped semiconductor region 232 and/or sixth doped semiconductor region 234. Thus, segments 252a and 252c of silicide layer 252 do not extend along sidewall surfaces 238b, 242a of fifth doped semiconductor region 232 and sixth doped semiconductor region 234, respectively.

By contrast, because patterned silicide blocking layer 248 was not formed over sidewall surface 238a of fifth doped semiconductor region 232 or sidewall surface 242b of sixth doped semiconductor region 234 silicide layer 252 is allowed to be formed on these surfaces. As described above, the stress caused by the interface between the different materials forming isolation structures 208, fifth doped semiconductor region 232 and/or sixth doped semiconductor region 234 may allow for formation of silicide along sidewall surfaces 238a, 242b (or wrap around the edges) of fifth doped semiconductor region 232 and sixth doped semiconductor region 234, respectively. This is because patterned silicide blocking layer 248 was not formed over (e.g., overlapping or straddling) portion 236b of fifth doped semiconductor region 232 and portion 240b of sixth doped semiconductor region 234. Thus, segments 252a and 252c of silicide layer 252 may extend along portions of sidewall surfaces 238a, 242b and portions 236b, 240b of top surfaces 236, 240 of fifth doped semiconductor region 232 and sixth doped semiconductor region 234, respectively.

However, as shown, because top surfaces 210 of isolation structures 208 were substantially coplanar with top surfaces 236, 240 of fifth doped semiconductor region 232 and sixth doped semiconductor region 234, respectively, prior to step 106, segments 252a and 252c of silicide layer 252 are limited (or inhibited) from extending too far along sidewall surfaces 238a, 242b of fifth doped semiconductor region 232 and sixth doped semiconductor region 234, respectively. Moreover, as described above, any extension of segments 252a and 252c of silicide layer 252 along sidewall surfaces 238a, 242b of fifth doped semiconductor region 232 and sixth doped semiconductor region 234 has minimal (or no) impact on device performance as these segments are not extending towards an underlying p-n junction interface. Thus, the extension of segments 252a and 252c of silicide layer 252 along sidewall surfaces 238a, 242b of fifth doped semiconductor region 232 and/or sixth doped semiconductor region 234 does not lead to leakage current issues.

In other examples, device 246 may include more contacts in each horizontal row (e.g., along x-direction) than shown in FIGS. 2L and 3E. In that regard, for ease of understanding reference is now made to FIG. 3F which illustrates a top-down view of a device 246’ that includes similar components as device 246 described above in FIG. 3E. In various examples, each of first contact 258a, second contact 258b, and third contact 258c may now include a plurality of contacts (e.g., 2, 3, 4, etc.). For example, first contact 258a and third contact 258c may each include two contacts, as shown in FIG. 3F. As another example, second contact 258b may include four contacts, as shown in FIG. 3F. FIG. 3F illustrates additional horizontal rows of contacts (e.g., along x-direction) but are not labeled for ease of understanding. In various examples, design and manufacture of device 246’ may include more than one discrete metal contact for each of first, second, and third contacts 258a, 258b, 258c. In other words, first contact 258a, second contact 258b, and/or third contact 258c may include one or more discrete metal contacts depending on the design requirements for a given semiconductor device.

Now referring to FIG. 2M, a device 260 with a misaligned patterned silicide blocking layer is illustrated. In various examples, a misalignment of a patterned silicide blocking layer may occur during the formation thereof at processing step 104 described above with respect to FIGS. 2F and 2G. For example, as shown in FIG. 2M, a misaligned patterned silicide blocking layer 262 is formed that covers a larger portion of top surface 222 of fourth doped semiconductor region 220 (e.g., on one side) than designed. That is, misaligned patterned silicide blocking layer 262 was unintentionally off-set over fourth doped semiconductor region 220 as a result of one or more semiconductor processing alignment and/or processing steps. In such examples, a portion of misaligned patterned silicide blocking layer 262 may be removed during the formation process of second contact 258b during step 108 described above with respect to FIGS. 2J and 2L.

As shown, second contact 258b extends through dielectric layer 256, liner layer 254, misaligned patterned silicide blocking layer 262 and lands on segment 252b of silicide layer 252 and top surface 222 of fourth doped semiconductor region 220. In other words, in such examples, second contact 258b interfaces (e.g., abuts, physically contacts, or the like) with misaligned patterned silicide blocking layer 262 (e.g., laterally interfaces), silicide layer 252 and top surface 222 of fourth doped semiconductor region 220. While the misalignment as shown may not have been intended, the misalignment results in little to no negative effects on device 260. Thus, the methods disclosed herein provide processing tolerances that allow for misalignment of patterned silicide blocking layer without negatively effecting the manufactured device.

In other examples, a gate structure (e.g., dummy gate structure) may be used as a patterned silicide blocking layer. For example, in reference to FIG. 2N, a device 264 is shown with similar features to device 200 except with respect to gate structures 266, 272 being used as a patterned silicide blocking layer (e.g., blocking structure). In that regard, gate structures 266, 272 are formed in lieu of patterned silicide blocking layer 244 during step 104 of method 100. In some examples, one or more of gate structures 266, 272 may be dummy gate structures in that the gate structures are non-functional gate structures. In some examples, the gate structures 266, 272 may be concurrently formed with functional gate structures (e.g., gate structures of field effect transistors (FETs) formed in other region of the semiconductor substrate 202).

As shown, gate structures 266, 272 include gate dielectric layers 271, 277 and gate electrode layers 268, 274, respectively. Gate dielectric layers 271, 277 are formed over portions 210a of top surfaces 210 of isolation structures 208 and over portions 222a of top surface 222 of fourth doped semiconductor region 220. Gate electrode layers 268, 274 are formed over gate dielectric layer 271, 277, respectively. Gate spacers 270, 276 are formed along sidewalls of gate structures 266, 272, and more specifically, along sidewalls of gate dielectric layers 271, 277 and gate electrode layers 268, 274, respectively.

Gate dielectric layers 271, 277, may, in various examples, include any dielectric material including a high-k dielectric material. For example, gate dielectric layer 271, 277 may include dielectric materials such as silicon oxide, silicon dioxide, hafnium oxide, zirconium oxide, silicon nitride, silicon oxynitride, or combinations thereof. In some examples, gate dielectric layers 271, 277 may further include an interfacial layer formed of a dielectric material such as an oxide material that is disposed under the high-k dielectric material. In various examples, gate dielectric layers 271, 277 may be formed by thermal oxidation, one or more chemical vapor deposition (CVD) processes, physical vapor deposition (PVD) processes, plasma-enhanced CVD (PECVD), or combinations thereof.

Gate electrode layers 268, 274 in various examples, may include a metal material such as titanium, nickel, titanium nitride, titanium tungsten, tungsten, or a combination thereof. Other metals and/or metal alloys may be used in gate electrode layers 268, 274 and are within the scope of this disclosure such that gate electrode layers 268, 274 may include, or be, any appropriate metal and/or metal alloy, or combination thereof. In various other examples, gate electrode layers 268, 274 may include polycrystalline silicon, also referred to as polysilicon. In various examples, gate electrode layers 268, 274 may be formed using one or more deposition processes, such as sputtering, physical vapor deposition (PVD), chemical vapor deposition (CVD), the like, or any combination thereof.

Gate spacers 270, 276, also referred to as dielectric spacers or sidewall spacers, in various examples, may include one or more layers of an oxide material (e.g., silicon oxide), a nitride material (e.g., silicon nitride and/or silicon oxynitride), or combinations thereof. Gate spacers 270, 276 may be formed using any known process, such as for example, chemical vapor deposition (CVD), and/or physical vapor deposition (PVD), among others. In various examples, a dielectric material may be formed over device 264 and which is subsequently etched to form gate spacers 270, 276.

As shown, silicide layer 252 includes segments 252a, 252b and 252c (e.g., conductive layers), respectively formed over fifth doped semiconductor region 232, fourth doped semiconductor region 220, and sixth doped semiconductor region 234. In that regard, as shown, gate structures 266, 272 and gate spacers 270, 276 (e.g., blocking structure) prevent the formation of silicide over portions 222a of top surface 222 of fourth doped semiconductor region 220. In other words, such positioning (or orientation) of gate structures 266, 272 and gate spacers 270, 276, in various examples, prevents the formation of silicide on portions of fourth doped semiconductor region 220 at and/or around the interface between fourth doped semiconductor region 220 and isolation structures 208. As such, gate structures 266, 272 and gate spacers 270, 276 (e.g., silicide blocking structure) prevent the formation of silicide along sidewall surfaces 224a-b of fourth doped semiconductor region 220.

Instead, segment 252b of silicide layer 252 is formed only on portion 222b of top surface 222 of fourth doped semiconductor region 220 that was exposed (e.g., uncovered/not covered) by gate structures 266, 272 and gate spacers 270, 276 (e.g., silicide blocking structure). That is, segment 252b of silicide layer 252 does not extend along sidewall surfaces 224a-b of fourth doped semiconductor region 220. By not extending along sidewall surfaces 224a-b of fourth doped semiconductor region 220 leakage current in device 264 may be decreased or prevented. This is because inadvertent leakage current may occur when silicide layer 252 extends along sidewall surfaces 224a-b (or wrap around the edges) of fourth doped semiconductor region 220 towards second doped semiconductor region 214b (e.g., p-n junction 223 between fourth doped semiconductor region 220 and second doped semiconductor region 214b).

In contrast, in various examples, segments 252a and 252c of silicide layer 252 extend to the interface between isolation structures 208 and either fifth doped semiconductor region 232 and/or sixth doped semiconductor region 234. As shown, the stress caused by the interface between the different materials forming isolation structures 208, fifth doped semiconductor region 232 and/or sixth doped semiconductor region 234 may allow for formation of silicide along sidewall surfaces 238a-b, 242a-b (or wrap around the edges) of fifth doped semiconductor region 232 and sixth doped semiconductor region 234, respectively. This is because gate structures 266, 272 and gate spacers 270, 276 (e.g., silicide blocking structure) were not formed over (e.g., overlapping or straddling) fifth doped semiconductor region 232 and sixth doped semiconductor region 234. Thus, segments 252a and 252c of silicide layer 252 may extend along sidewall surfaces 238a-b, 242a-b and the top surfaces 236, 240 of fifth doped semiconductor region 232 and sixth doped semiconductor region 234, respectively.

However, as shown, because top surfaces 210 of isolation structures 208 were substantially coplanar with top surfaces 236, 240 of fifth doped semiconductor region 232 and sixth doped semiconductor region 234, respectively, prior to step 106 of method 100, segments 252a and 252c of silicide layer 252 are limited (or inhibited) from extending too far along sidewall surfaces 238a, 242b of fifth doped semiconductor region 232 and sixth doped semiconductor region 234, respectively. Moreover, as described above, any extension of segments 252a and 252c of silicide layer 252 along sidewall surfaces 238a-b, 242a-b of fifth doped semiconductor region 232 and sixth doped semiconductor region 234 has minimal (or no) impact on device performance as these segments are not extending towards an underlying p-n junction interface. Thus, the extension of segments 252a and 252c of silicide layer 252 along sidewall surfaces 238a-b, 242a-b of fifth doped semiconductor region 232 and/or sixth doped semiconductor region 234 does not lead to leakage current issues.

In other examples, as shown in reference to FIG. 2O, gate structures and gate spacers, may be used as a patterned silicide blocking layer, that extends continuously from over fourth doped semiconductor region 220 to over fifth doped semiconductor region 232 and/or sixth doped semiconductor region 234. In that regard, FIG. 2O illustrates a device 278 that is similar to device 264 of FIG. 2N except with respect to the orientation (or configuration) of the gate structures and gate spacers being used as a blocking structure. Descriptions of similar features may not be repeated below.

In contrast to device 264 described in reference to FIG. 2N, device 278 has gate structures 280, 288 that extend continuously from over fourth doped semiconductor region 220 to over fifth doped semiconductor region 232 and sixth doped semiconductor region 234, respectively. As shown, gate structures 280, 288 include gate dielectric layers 282, 290 and gate electrode layers 284, 292, respectively. Gate dielectric layers 282, 290 are formed over portions 222a of top surface 222 of fourth doped semiconductor region 220, over top surfaces 210 of isolation structures 208, over portion 236a of top surface 236 of fifth doped semiconductor region 232, and over portion 240a of top surface 240 of sixth doped semiconductor region 234. Gate electrode layers 284, 292 are formed over gate dielectric layer 282, 290, respectively. Gate spacers 286, are formed along sidewalls of gate structures 280, 288, and more specifically, along sidewalls of gate dielectric layers 282, 290 and gate electrode layers 284, 292, respectively. Gate structures 280, 288, including gate dielectric layers 282, 290 and gate electrode layers 284, 292, and gate spacers 286, 294 may be formed in similar manners and of similar materials as those described above with respect to gate structures 266, 272, including gate dielectric layers 271, 277 and gate electrode layers 268, 274, and gate spacers 270, 276 in reference to FIG. 2N.

As shown, gate structures 280, 288 (including gate spacers 286, 294) additionally cover portions of fifth doped semiconductor region 232 and sixth doped semiconductor region 234, preventing formation of silicide layer 252 on the covered portions. Specifically, gate structures 280, 288 and gate spacers 286, 294 are further formed on portions 236a, 240a of fifth doped semiconductor region 232 and sixth doped semiconductor region 234, respectively, preventing silicide layer 252 from being formed thereon. In other words, segments 252a and 252c of silicide layer 252 do not extend to the interface between isolation structures 208 and sidewall surfaces 238b, 242a of fifth doped semiconductor region 232 and sixth doped semiconductor region 234, respectively. Thus, segments 252a and 252c of silicide layer 252 do not extend along sidewall surfaces 238b, 242a of fifth doped semiconductor region 232 and sixth doped semiconductor region 234, respectively. Accordingly, as shown in FIG. 2O, gate structures 280, 288 and gate spacers 286, 294 (e.g., silicide blocking structure) prevent the formation of silicide layer 252 on sidewall surfaces 224a-b and portions 222a of top surface 222 of fourth doped semiconductor region 220, on sidewall surface 238b and portion 236a of top surface 236 of fifth doped semiconductor region 232, and on sidewall surface 242a and portion 240a of top surface 240 of sixth doped semiconductor region 234.

In various other examples, depending on the material used, silicide layer 252 may form over at least a portion of the gate electrode layers (e.g., gate electrode layers 268, 274, 284, 292 depicted in FIGS. 2N and 2O). In that regard, when the gate electrode layers include polysilicon, silicide may be formed on exposed surfaces of the polysilicon.

In various examples, fourth doped semiconductor region 220, fifth doped semiconductor region 232, and sixth doped semiconductor region 234 may be formed after forming the gate structures (e.g., gate structures 266, 272, 280, 288) and sidewall spacers (e.g., sidewall spacers 270, 276, 286, 294). In that regard, the gate structures and sidewall spacers may be formed as described above (e.g., over one or more of first, second, or third doped semiconductor regions 214a, 214b, 214c and isolation structures 208). First patterned photoresist layer 216 may then be formed to cover first and third doped semiconductor regions 214a, 214c and expose second semiconductor region 214b. Second implant process 218 may then be performed, as described above, to form fourth doped semiconductor region 220. Thereafter, first patterned photoresist layer 216 is removed and subsequently second patterned photoresist layer 228 may be formed to cover fourth doped semiconductor region 220 and expose first and third doped semiconductor regions 214a, 214c. Third implant process 230 may then be performed, as described above, to form fifth doped semiconductor region 232 and sixth doped semiconductor region 234. Accordingly, the steps of method 100 may be performed in a different order while remaining within the scope of this disclosure.

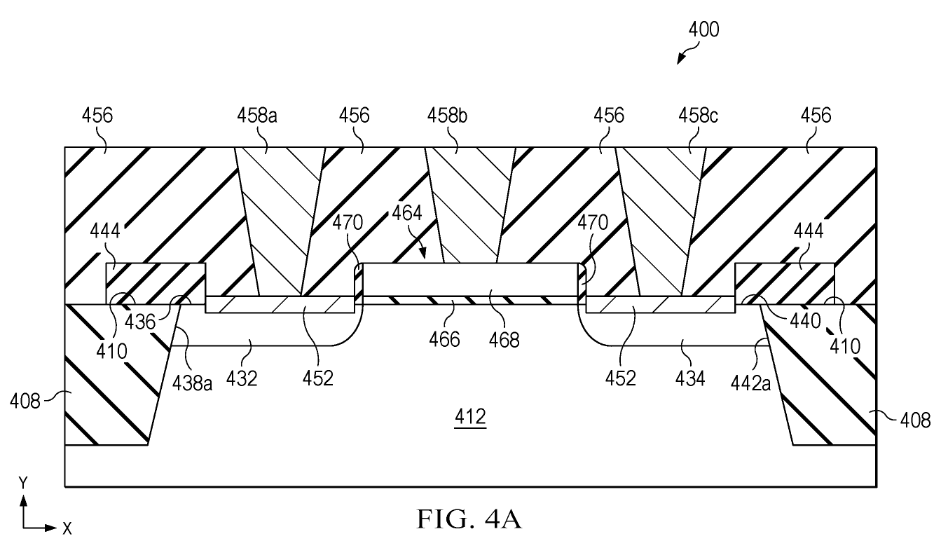

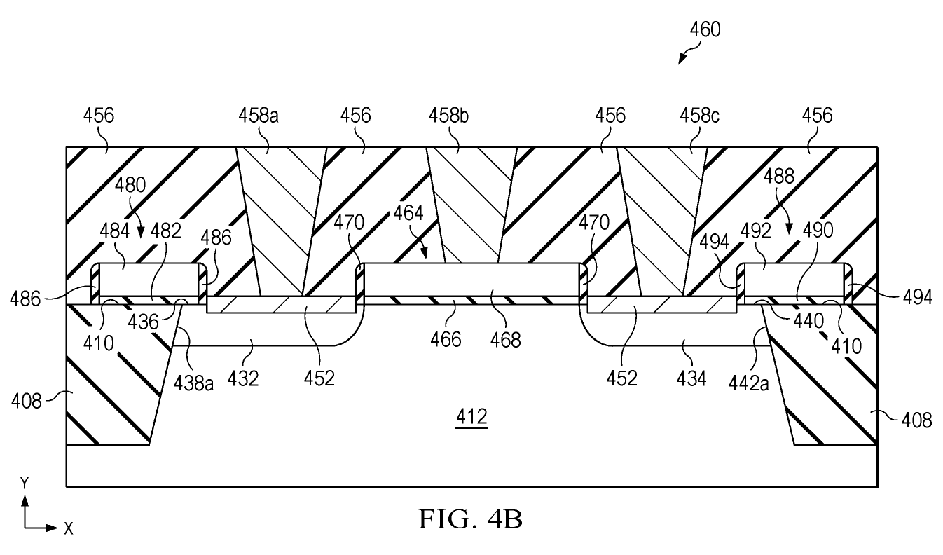

Referring now to FIG. 4A, a cross section view of a device 400 fabricated in accordance with various aspects of the present disclosure (such as those associated with method 100 of FIG. 1) is illustrated. In various examples, device 400 may be a field effect transistor (FET), a metal oxide semiconductor FET (MOSFET), a complementary metal oxide semiconductor FET (CMOS), or the like. Device 400 includes similar aspects as device 200 described above, including a semiconductor substrate 412, isolation structures 408, a patterned silicide blocking layer 444, a silicide layer 452, a dielectric layer 456, and contacts 458a-c (e.g., first contact 458a, second contact 458b, and third contact 458c), descriptions of which may not be repeated below. Device 400 further includes a source 432, a drain 434, a gate structure 464, and gate spacers 470.

Source 432 and drain 434 are formed in semiconductor substrate 412 on either side of gate structure 464. In various examples, source 432 and drain 434 may be doped using an n-type dopant or a p-type dopant. In various examples, a channel region (within semiconductor substrate 412) extends under gate structure 464 from source 432 to drain 434. In various examples, source 432 and/or drain 434 may extend from under gate spacers 470 (or gate structure 464) to isolation structures 408.

In various examples, source 432 and drain 434 are doped to have a first conductivity type and the semiconductor substrate (including the channel region) is doped to have a second conductivity type that is opposite the first conductivity type. As such, in various examples, p-n junctions may be formed between source 432 or drain 434 and semiconductor substrate 412 (including the channel region). In other words, the interface between source 432 or drain 434 and semiconductor substrate 412 forms a p-n junction as a result of the difference in dopant types (e.g., opposite conductivity types) used in source 432 or drain 434 and semiconductor substrate 412.

Gate structure 464 further includes a gate dielectric layer 466 and a gate electrode layer 468. Gate dielectric layer 466 is formed over semiconductor substrate 412 and gate electrode layer 468 is formed over gate dielectric layer 466. Gate spacers 470 are formed along sidewalls of gate structure 464, and more specifically, along sidewalls of gate dielectric layer 466 and gate electrode layer 468. Gate structures 280, 288, including gate dielectric layer 466 and gate electrode layer 468, and gate spacers 470 may be formed in similar manners and of similar materials as those described above with respect to gate structures 266, 272, including gate dielectric layers 271, 277 and gate electrode layers 268, 274, and gate spacers 270, 276 in reference to FIG. 2N.

As shown in FIG. 4A, silicide layer 452 is formed on source 432 and drain 434 and extends between gate spacers 470 and patterned silicide blocking layer 444. In some examples, silicide layer 452 abuts (e.g., physically contacts, interfaces, or the like) patterned silicide blocking layer 444. Moreover, as described above, patterned silicide blocking layer 444 prevents silicide layer 452 from forming on portions of source 432 and drain 434 that are covered by patterned silicide blocking layer 444. Specifically, patterned silicide blocking layer 444 (e.g., blocking structure) is formed over a portion of top surface 436 of source 432, over a portion of top surface 440 of drain 434, and over portions of top surfaces 410 of isolation structures 408 as shown in FIG. 4A. In other words, patterned silicide blocking layer 444 straddles (or overlaps) a portion of top surface 436 of source 432, a portion of top surface 440 of drain 434, and portions of top surfaces 410 of isolation structures 408.

Such positioning (or orientation) of the patterned silicide blocking layer 444, in various examples, prevents the formation of silicide on the covered portions of source 432 and drain 434 at and/or around the interface between source 432 and drain 434 and isolation structures 408 which may decrease leakage current in device 400. Thus, as shown, silicide layer 452 is prevented from forming along portions of the respective top surfaces 436, 440 and sidewall surfaces 438a, 442a of source 432 and drain 434 by patterned silicide blocking layer 444. By not extending along sidewall surfaces 438a, 442a of source 432 and drain 434 leakage current in device 400 may be decreased or prevented. This is because inadvertent leakage current may occur when silicide layer 452 extends along sidewall surfaces 438a, 442a (or wrap around the edges) of source 432 and drain 434 towards semiconductor substrate 412 (e.g., p-n junction between source 432 or drain 434 and semiconductor substrate 412).

In other examples, as described above, a gate structure (e.g., dummy gate structure) may be used as a patterned silicide blocking layer. For example, in reference to FIG. 4B, a device 460 is shown with similar features to device 400 except with respect to gate structures 480, 488 being used as a patterned silicide blocking layer. In that regard, gate structures 480, 488 of device 460 have replaced patterned silicide blocking layer 444 of device 460 in FIG. 4A. In some examples, one or more of gate structures 480, 488 may be dummy gate structures in that the gate structures are non-functional gate structures. In other examples, one or more of gate structures 480, 488 may be functional gate structures.

As shown, gate structures 480, 488 include gate dielectric layers 482, 490 and gate electrode layers 484, 492, respectively. Gate dielectric layers 482, 490 are formed over portions of top surfaces 410 of isolation structures 408, over a portion of top surface 436 of source 432, and over a portion of top surface 440 of drain 434. Gate electrode layers 484, 492 are formed over gate dielectric layers 482, 490, respectively. Gate spacers 486, 494 are formed along sidewalls of gate structures 480, 488, and more specifically, along sidewalls of gate dielectric layers 482, 490 and gate electrode layers 484, 492, respectively. Gate structures 480, 488, including gate dielectric layers 482, 490 and gate electrode layers 484, 492, and gate spacers 486, 494 may be formed in a similar manner and of similar materials as those described above with respect to gate structures 464, including gate dielectric layer 466 and gate electrode layer 468, and gate spacers 470 in reference to FIG. 4A.

Gate structures 480, 488 and gate spacers 486, 494 are formed on a portion of top surface 436 of source 432, a portion of top surface 440 of drain 434, and portions of top surfaces 410 of isolation structures 408 as shown in FIG. 4B. In other words, Gate structures 480, 488 (including gate spacers 486, 494) straddle (or overlap) a portion of top surface 436 of source 432, a portion of top surface 440 of drain 434, and portions of top surfaces 410 of isolation structures 408. Such positioning (or orientation) of gate structures 480, 488 and gate spacers 486, 494, in various examples, prevents the formation of silicide on these covered portions of source 432 and drain 434 at and/or around the interface between source 432 or drain 434 and isolation structures 408 which may decrease leakage current in device 460.

Accordingly, as shown, silicide layer 452 is prevented from forming along portions of the respective top surfaces 436, 440 and sidewall surfaces 438a, 442a of source 432 and drain 434 by gate structures 480, 488 and gate spacers 486, 494. By not extending along sidewall surfaces 438a, 442a of source 432 and drain 434 leakage current in device 460 may be decreased or prevented. This is because inadvertent leakage current may occur when silicide layer 452 extends along sidewall surfaces 438a, 442a (or wrap around the edges) of source 432 and drain 434 towards semiconductor substrate 412 (e.g., p-n junction between source 432 or drain 434 and semiconductor substrate 412).

Accordingly, the methods and devices disclosed herein provide improved processes for reducing leakage current in semiconductor devices. As described herein, a blocking structure (e.g., patterned silicide blocking layer) may be formed over an interface between a semiconductor region (e.g., doped semiconductor region, source/drain region, active region, etc.) and an isolation structure. That is, the blocking structure straddles (or overlaps) at least a portion of the semiconductor region and at least a portion of the isolation structure. Such positioning (or orientation) of the blocking structure, in various examples, prevents the formation of silicide on portions of the semiconductor region at and/or around the interface between the semiconductor region and the isolation structure which may decrease leakage current in the semiconductor device.

In that regard, after forming the blocking structure (e.g., patterned silicide blocking layer), a metal layer may be formed over the semiconductor device, including over the blocking structure and the semiconductor region. The blocking structure prevents formation of the metal layer on those portions of the semiconductor region that are covered by the blocking structure. An annealing process may then be performed after which silicide (e.g., conductive layer) is formed as a result of the metal layer reacting with the semiconductor region. In other words, the metal atoms from the metal layer react with silicon from the semiconductor region to form the silicide over a top surface of the semiconductor region (and not along the sidewall surfaces of the semiconductor region) that are uncovered by the blocking structure. Accordingly, the patterned silicide blocking layer prevents the formation of silicide along sidewall surfaces of the semiconductor region which decreases leakage current in the semiconductor device.

By preventing the formation of silicide along sidewalls of semiconductor regions leakage current in semiconductor devices may be decreased or prevented. Leakage current in semiconductor devices may be caused and/or enhanced by the silicide that is allowed to extend along sidewalls (or wrap around the edges) of semiconductor region towards a p-n junction. Reducing and/or removing silicide formation from along sidewalls (or edges) of semiconductor regions decreases and/or prevents leakage current that may be caused by the silicide. The devices formed using the methods and processes disclosed herein exhibit reduced leakage current as compared to baseline methods. This improvement may be attributed to the patterned silicide blocking layer preventing the silicide layer from forming along sidewalls of the semiconductor region (e.g., doped semiconductor region, source/drain region, active region, etc.).

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A device, comprising:
a first semiconductor region disposed over a substrate, the first semiconductor region having a first conductivity type;
a second semiconductor region disposed over the first semiconductor region, the second semiconductor region having a second conductivity type opposite the first conductivity type;
an isolation structure disposed over the substrate, the isolation structure abutting the second semiconductor region;
a blocking structure straddling over a first portion of the second semiconductor region and a portion of the isolation structure; and
a conductive layer disposed over a second portion of the second semiconductor region, the conductive layer abutting the blocking structure.

2. The device of claim 1, wherein the conductive layer includes a silicide layer.

3. The device of claim 1, further comprising:
a third semiconductor region disposed over the substrate, the third semiconductor region having the first conductivity type, wherein:
the isolation structure extends from the second semiconductor region to the third semiconductor region; and
the blocking structure interfaces with the portion of the isolation structure.

4. The device of claim 3, wherein the conductive layer is a first conductive layer, the device further comprising:
a second conductive layer; and
wherein the second conductive layer is disposed over the third semiconductor region.

5. The device of claim 3, wherein the blocking structure extends continuously from over the second semiconductor region to over the third semiconductor region.

6. The device of claim 5, wherein the conductive layer is a first conductive layer, the device further comprising:
a second conductive layer, wherein the second conductive layer is disposed over a first portion of the third semiconductor region while the blocking structure is disposed over a second portion of the third semiconductor region.

7. The device of claim 1, wherein the second semiconductor region has a sidewall having a first portion that interfaces with the isolation structure and a second portion that interfaces with the blocking structure.

8. The device of claim 1, wherein a p-n junction is formed at an interface between the second semiconductor region and the first semiconductor region.

9. The device of claim 1, wherein the blocking structure includes a dielectric material or polycrystalline silicon.

10. The device of claim 1, further comprising:
a contact feature extending to the conductive layer, wherein the blocking structure laterally interfaces with the contact feature.

11. The device of claim 10, wherein a first portion of the contact feature lands on the conductive layer and a second portion of the contact feature lands on the second semiconductor region.

12. A device, comprising:
a first semiconductor region and a second semiconductor region disposed over a substrate, the first semiconductor region having a first conductivity type and the second semiconductor region having a second conductivity type that is opposite the first conductivity type;
an isolation region disposed adjacent to and laterally surrounding the first and second semiconductor regions;
a blocking structure straddling over a first portion of the second semiconductor region and a portion of the isolation region; and
a conductive layer disposed over a second portion of the second semiconductor region.

13. The device of claim 12, wherein the conductive layer includes a silicide layer.

14. The device of claim 13, wherein the silicide layer includes a metal selected from the group consisting of titanium (Ti), nickel (Ni), cobalt (Co), tungsten (W), molybdenum (Mo), platinum (Pt), and chromium (Cr).

15. The device of claim 12, wherein the second semiconductor region has a sidewall having a first portion that interfaces with the isolation region and a second portion that interfaces with the blocking structure.

16. The device of claim 12, further comprising:
a third semiconductor region disposed over the substrate, the isolation region further disposed adjacent the third semiconductor region, wherein the blocking structure is further disposed over a portion of the third semiconductor region.

17. The device of claim 12, further comprising:
a gate structure of a transistor disposed over the first semiconductor region, wherein:
the first semiconductor region is a channel region of the transistor;
the second semiconductor region is a source/drain region of the transistor; and
the isolation region is a shallow trench isolation structure.

18. A method, comprising:
forming a dielectric isolation structure in a semiconductor layer;
forming a blocking layer over a first portion of the semiconductor layer and over a portion of the dielectric isolation structure; and
forming a conductive layer over a second portion of the semiconductor layer.

19. The method of claim 18, further comprising:
forming a first semiconductor region in the semiconductor layer, the first semiconductor region having a first conductivity type;
forming a second semiconductor region in the semiconductor layer, the second semiconductor region having a second conductivity type that is opposite the first conductivity type; and
forming the blocking layer over the first portion of the semiconductor layer includes forming the blocking layer on a portion of the second semiconductor region without forming the blocking layer on any portion of the first semiconductor region.

20. The method of claim 18, further comprising:
forming an interlayer dielectric layer over the conductive layer and the blocking layer;
removing portions of the interlayer dielectric layer and the blocking layer to form an opening; and
forming a contact feature within the opening.
